(19) United States
(12) Patent Application Publication
(10) Pub. No.: US 2023/0189659 A1
(43) Pub. Date: Jun. 15, 2023

(54) SYNTHETIC ANTIFERROMAGNET-BASED PROBABILISTIC COMPUTING DEVICES

(71) Applicant: Intel Corporation, Santa Clara, CA (US)

(72) Inventors: Punyashloka Debashis, Hillsboro, OR (US); Tanay A. Gosavi, Portland, OR (US); Hai Li, Portland, OR (US); Chia-Ching Lin, Portland, OR (US); Dmitri Evgenievich Nikonov, Beaverton, OR (US); Kaan Oguz, Portland, OR (US); Ashish Verma Penumatcha, Beaverton, OR (US); Marko Radosavljevic, Portland, OR (US); Ian Alexander Young, Olympia, WA (US)

(73) Assignee: Intel Corporation, Santa Clara, CA (US)

(21) Appl. No.: 17/550,663

(22) Filed: Dec. 14, 2021

(51) Int. Cl. H01L 43/02; H01L 43/04; H01L 43/10; H01L 43/12; H01L 43/14

(52) U.S. Cl. CPC H01L 43/02; H01L 43/04; H01L 43/10; H01L 43/12; H01L 43/14; G06F 7/58

(57) ABSTRACT

A probabilistic bit (p-bit) comprises a magnetic tunnel junction (MTJ) comprising a free layer whose magnetization orientation randomly fluctuates in the presence of thermal noise. The p-bit MTJ comprises a reference layer, a free layer, and an insulating layer between the reference and free layers. The reference layer and the free layer comprise synthetic antiferromagnets. The use of a synthetic antiferromagnet for the reference layer reduces the amount of stray magnetic field that can impact the magnetization of the free layer and the use of a synthetic antiferromagnet for the free layer reduces stray magnetic field bias on p-bit random number generation. Tuning the thickness of the nonmagnetic layer of synthetic antiferromagnet free layer can result in faster random number generation time relative to a comparable MTJ with a free layer comprising a single-layer ferromagnet.

### BACKGROUND

Probabilistic computing can enable the hardware acceleration of certain computing tasks. Probabilistic bits comprise one or more spintronic devices that can generate random numbers with a tunable probability.

### BRIEF DESCRIPTION OF THE DRAWINGS

FIG. 1 illustrates an example spin-torque transfer (STT) magnetic tunnel junction (MTJ).

FIG. 2 illustrates an example spin-orbit torque (SOT) MTJ.

FIG. 3 is a chart showing the output voltage of an example p-bit as a function of time.

FIG. 4 is a chart illustrating the tunability of p-bits.

FIG. 5 illustrates two sources of fluctuation bias in an MTJ.

FIG. 6 illustrates a first example STT MTJ comprising a synthetic antiferromagnet free layer.

FIG. 7 illustrates a second example STT p MTJ bit a synthetic antiferromagnet free layer.

FIG. 8 is a chart illustrating the dependency of interlayer exchange coupling (RKKY coupling, J_{RKKY}) on spacer thickness for an example synthetic antiferromagnet.

FIG. 9 illustrates a first example SOT MTJ with a synthetic antiferromagnet free layer.

FIG. 10 illustrates a second example SOT MTJ with a synthetic antiferromagnet free layer.

FIG. 11 illustrates simulated external magnetic pinning field strength for a ferromagnet as a function of structure size.

FIG. 12 illustrates simulated autocorrelation time of the magnetization fluctuation in a single-layer ferromagnet and synthetic antiferromagnet structures.

FIGS. 13A-13B illustrate an example p-bit comprising an MTJ operating as a reference resistor.

FIG. 14 illustrates an example weighted summing circuit utilizing MTJ-based p-bits.

FIG. 15 is an example method of forming an MTJ comprising synthetic antiferromagnets.

FIG. 16 is a top view of a wafer and dies that may be included in a microelectronic assembly, in accordance with any of the embodiments disclosed herein.

FIG. 17 is a cross-sectional side view of an integrated circuit device that may be included in a microelectronic assembly, in accordance with any of the embodiments disclosed herein.

FIGS. 18A-18D are perspective views of example planar, FinFET, gate-all-around, and stacked gate-all-around transistors.

FIG. 19 is a cross-sectional side view of an integrated circuit device assembly that may include a microelectronic assembly, in accordance with any of the embodiments disclosed herein.

FIG. 20 is a block diagram of an example electrical device that may include a microelectronic assembly, in accordance with any of the embodiments disclosed herein.

### DETAILED DESCRIPTION

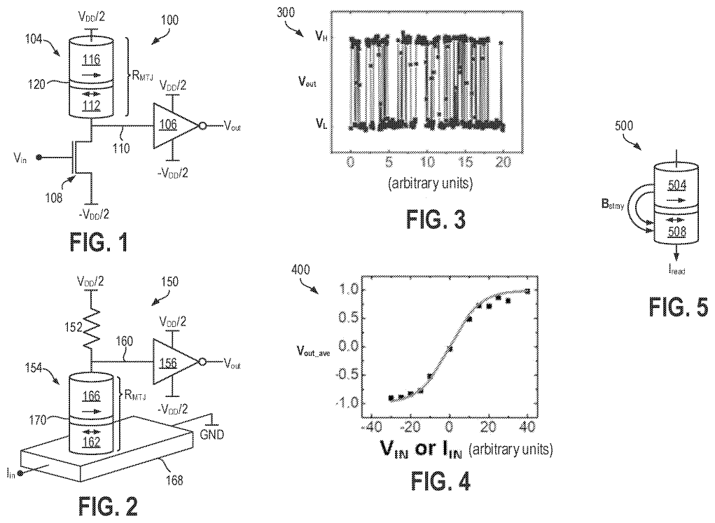

Probabilistic computing enables the hardware acceleration of various computing tasks, such as those related to optimization problems, sampling, inference, autonomous learning, and the emulation of a subclass of quantum computing. FIGS. 1-2 illustrate one type of device that can enable the hardware acceleration of these tasks, a probabilistic bit (or p-bit), which is a spintronic-based stochastic device that generates random numbers with a tunable probability. FIG. 1 illustrates an example spin-torque transfer (STT) p-bit. The STT p-bit 100 comprises a magnetic tunnel junction (MTJ) 104, acting as a load or reference resistor, in series with an NMOS transistor 108. An intermediate node 110 between the MTJ 104 and the NMOS transistor 108 is connected to the input of an inverter 106, the output of which is the output of the p-bit 100 (Vout).

The MTJ 104 comprises a comprising a low barrier ferromagnet free layer 112, a reference layer 116, and an insulating layer 120. The MTJ 104 is an in-plane MTJ, as indicated by the arrows illustrated in the free layer 112 and the reference layer 116. The resistance (R_{MTJ}) of the MTJ 104 fluctuates between two values, R_{AP} and R_{P}, as the magnetization of the free layer 112 randomly switches its direction between being parallel (R_{P}) and antiparallel (R_{AP}) to that of the reference layer 116 due to thermal noise. The random fluctuations in R_{MTJ} produce random values at the output (Vₒᵤₜ) of the p-bit 100 that fluctuate between V_{H} (a logical “high” or “1” value) and V_{L} (a logical “low” or “0” value). The probability of Vₒᵤₜ being high or low is tunable through adjustment of an input voltage (Vᵢₙ) applied to the gate of the NMOS transistor 108.

FIG. 2 illustrates an example spin-orbit torque (SOT) p-bit. The SOT p-bit 150 comprises a reference resistor 152 in series with an MTJ 154. The MTJ 154, like MTJ 104, is an in-plane MTJ. An intermediate node 160 between the MTJ 154 and the resistor 152 is connected to the input of an inverter 156, the output of which is the output of the p-bit 150. The MTJ 154 is similar to the MTJ 104 of FIG. 1 and comprises a free layer 162, a reference layer 166, and an insulating layer 170. The free layer 162 is positioned adjacent to a spin-orbit torque electrode 168. The resistance of the magnetic tunnel junction 154 fluctuates between two values (R_{AP} and R_{P}) as the magnetization of the free layer 162 randomly switches its direction due to thermal noise, producing random binary bits at the output of the p-bit 150. The probability of the output of the p-bit 150 being high or low is tunable through adjustment of an input current (Iᵢₙ) that passes through a spin-orbit torque electrode 168 as an in-plane current. The in-plane current causes a polarized spin current to be injected into the free layer ferromagnet 162, which exerts enough of a spin torque on the free layer ferromagnet 162 to influence its magnetization.

FIG. 3 is a chart showing the output voltage of an example p-bit as a function of time. The chart 300 shows Vₒᵤₜ of a p-bit (e.g., p-bits 100, 150) fluctuating between a high value (V_{H}) and a low value (V_{L}) over time. FIG. 4 is a chart illustrating the tunability of p-bits. The chart 400 shows the average output voltage of a p-bit as a function of input voltage or current (shown in arbitrary units).

Two factors that can influence the applicability of p-bits for probabilistic computing applications include the tunability of the probability of random numbers generated and the speed at which the random numbers can be generated. Without any input (or with an unbiased input signal (e.g., Vᵢₙ=0, Iᵢₙ=0)), the generated random output values of a p-bit should be distributed between its “1” and “0” values with 50% probability. This probability should only be controlled by an input voltage (or current) to the p-bit, which can be, for example, the voltage output of another p-bit or the voltage output of multiple p-bits fed to the input through an interconnection matrix.

The speed of random number generation, which is characterized by the inverse of the autocorrelation time (τ_{N}) of the output fluctuation of the p-bit, is desired to be fast. Thus, τ_{N} should be made as small as possible. An in-plane MTJ (an MTJ in which the magnetization orientation of its constituent ferromagnets are in the plane of the ferromagnet thin films) with negligible in-plane shape anisotropy in its free layer has a large demagnetization field H_{D} in the free layer ferromagnet volume. This leads to fast fluctuations of the magnetization of the free layer ferromagnet in the presence of a thermal noise field Hₜₕ.

The correlation time of fluctuations in the magnetization orientation in the free layer ferromagnet is given by Equation (1):

$${τ}_{N} = \frac{1}{{α}^{1 / 3} γ {H}_{D}^{2 / 3} {H}_{th}^{1 / 3}} , \qquad Eq ( 1 )$$

$$where$$

$${H}_{th} = \frac{{k}_{B} T}{{M}_{s} V} , \qquad Eq ( 2 )$$

and α, γ, Mₛ and V are the damping constant, gyromagnetic ratio, saturation magnetization, and the volume of the free layer ferromagnet, respectively, and k_{B} is the Boltzmann constant and T is the temperature.

Thus, increasing the demagnetization field (H_{D}) of the free layer ferromagnet is one way by which faster fluctuations in p-bit outputs can be achieved. The upper limit of the demagnetization field in the free layer ferromagnet is determined by its saturation magnetization (Mₛ), which is fixed for a selected ferromagnetic material. By using a ferromagnetic material with larger Mₛ, a larger H_{D} can be achieved. However, this also increases the total magnetic moment, which is undesirable.

P-bits with both STT and SOT designs can suffer from biases that cause unequal distribution in their output values. A first source of bias is the influence that any stray magnetic field emanating from the reference layer may have on the free layer of the MTJ. As the stray field prefers one magnetization direction over its antiparallel direction, the random numbers generated by a p-bit can be biased away from an even distribution of “1” and “0” output values. The use of a synthetic antiferromagnet as the reference layer can reduce the total stray field emanating from the reference layer. In some existing MTJs comprising synthetic antiferromagnets reference layers, the stray field can be about 5 mT, which is enough to bias the magnetization fluctuations of the free layer ferromagnet. To compensate for the reference layer stray field, in some existing in-plane MTJ-based p-bits, an external magnetic field is employed.

A second source of bias in random number generation in p-bits utilizing MTJs is the current that can flow through the MTJ as the resistance of the MTJ fluctuates. Like the stray field emanating from the reference layer, this current can influence the magnetization of the MTJ free layer and bias the probability of the output of a p-bit. FIG. 5 illustrates these two sources of fluctuation bias in an MTJ 500: stray magnetic fields (B_{stray}) emanating from a reference layer 504 and current (I_{read}) flowing through the MTJ 500.

Described herein are tunable MTJs that comprise a synthetic antiferromagnet free layer. Such devices can be used in probabilistic computing devices, such as p-bits. The use of a synthetic antiferromagnet as the free layer enables fast random number generation and has improved robustness against stray magnetic fields. The speed of random number generation can be adjusted by tailoring the thickness of the nonmagnetic layer of the synthetic antiferromagnet to have a high degree of interlayer exchange coupling between the ferromagnetic layers of the synthetic antiferromagnet.

The advantages of the tunable probabilistic computing devices disclosed herein include improved robustness to stray magnetic fields and reduced current bias relative to MTJ-based p-bits having a single ferromagnet free layer, which may provide for the operation of p-bits without the application of an external magnetic field. The disclosed spintronic-based probabilistic computing devices are expected to have a physical footprint at least 1,000 times less than and an energy efficiency at least ten times better than that of an equivalent CMOS implementation. The proposed devices are further expected to be at least ten times more robust against external unwanted magnetic fields than p-bits comprising MTJs with single ferromagnet free layers.

In the following description, specific details are set forth, but embodiments of the technologies described herein may be practiced without these specific details. Well-known circuits, structures, and techniques have not been shown in detail to avoid obscuring an understanding of this description. Phrases such as “an embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Furthermore, the terms “comprising,” “including,” “having,” and the like, as used with respect to embodiments of the present disclosure, are synonymous. The terms “substantially,” “close,” “approximately,” “near,” and “about” may refer to being within +/−10% of a target value unless otherwise specified. Similarly, terms describing spatial relationships, such as “perpendicular,” “orthogonal,” or “coplanar,” may refer to being substantially within the described spatial relationships (e.g., within +/−10 degrees of orthogonality).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is positioned adjacent to a layer Y refers to a layer that is in physical contact with layer Y.

Certain terminology may also be used in the following description for the purpose of reference only, and thus are not intended to be limiting. For example, terms such as “upper,” “lower,” “above,” “below,” “bottom,” and “top” refer to directions in the drawings to which reference is made. Terms such as “front,” “back,” “rear,” and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein, the term “integrated circuit component” refers to a packaged or unpacked integrated circuit product. A packaged integrated circuit component comprises one or more integrated circuit dies mounted on a package substrate with the integrated circuit dies and package substrate encapsulated in a casing material, such as a metal, plastic, glass, or ceramic. In one example, a packaged integrated circuit component contains one or more processor units mounted on a substrate with an exterior surface of the substrate comprising a solder ball grid array (BGA). In one example of an unpackaged integrated circuit component, a single monolithic integrated circuit die comprises solder bumps attached to contacts on the die. The solder bumps allow the die to be directly attached to a printed circuit board. An integrated circuit component can comprise one or more of any computing system component described or referenced herein or any other computing system component, such as a processor unit (e.g., system-on-a-chip (SoC), processor core, graphics processor unit (GPU), accelerator, chipset processor), I/O controller, memory, or network interface controller.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims

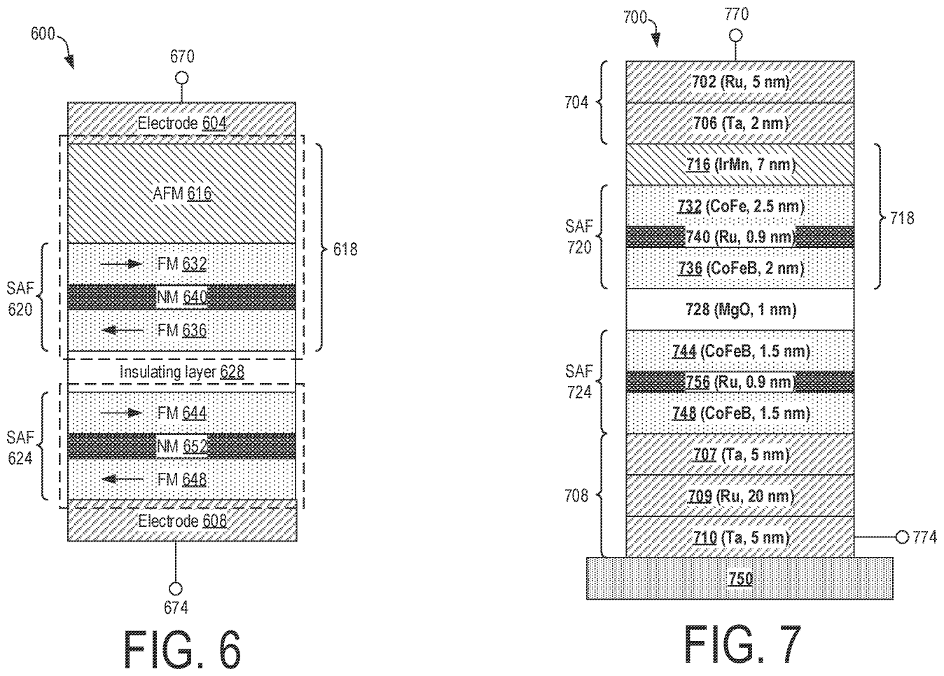

FIG. 6 illustrates a first example STT MTJ comprising a synthetic antiferromagnet free layer. The STT (spin-transfer torque) MTJ 600 is a two-terminal device with a first electrode 604 acting as a first terminal 670 and a second electrode 608 acting as a second terminal 674. The MTJ 600 comprises the first electrode 604, the second electrode 608, an antiferromagnet (AFM) 616, a first synthetic antiferromagnet 620, a second synthetic antiferromagnet (synthetic antiferromagnet free layer) 624, and an insulating layer 628 positioned between the first synthetic antiferromagnet 620 and the second synthetic antiferromagnet 624. The antiferromagnet 616 is positioned between the first electrode 604 and the first synthetic antiferromagnet 620. A large exchange bias effect between the antiferromagnet 616 and the adjacent ferromagnet in the synthetic antiferromagnet 620 (ferromagnet 632) pins the magnetization orientation of the adjacent ferromagnet, thereby enabling the combination of the synthetic antiferromagnet 620 and the antiferromagnet 616 to act as a reference layer (synthetic antiferromagnet reference layer) for the MTJ 600.

A synthetic antiferromagnet comprises two ferromagnets with a nonmagnetic layer or spacer positioned between them. Interlayer exchange coupling of the ferromagnets through the nonmagnetic spacer of an appropriate thickness results in antiparallel magnetization of the ferromagnets. The first synthetic antiferromagnet 620 comprises a first ferromagnet (FM) 632, a second ferromagnet 636, and a nonmagnetic (NM) layer 640 positioned between the first ferromagnet 632 and the second ferromagnet 636. The synthetic antiferromagnet free layer 624 comprises a third ferromagnet 644, a fourth ferromagnet 648, and a nonmagnetic layer 652 positioned between the third ferromagnet 644 and the fourth ferromagnet 648. The ferromagnet pairs 632-636 and 644-648 have substantially opposite magnetization orientations, as indicated by the arrows in FIG. 6. The magnetic moments of the third and fourth ferromagnets 644 and 648 are designed to match. That is, the saturation magnetization of the third ferromagnet 644 times the thickness of the third ferromagnet 644 is equal to the saturation magnetization of the fourth ferromagnet 648 times the thickness of the fourth ferromagnet 648. This makes the effective magnetic moment of the synthetic antiferromagnet free layer 624 close to zero and any external magnetic field (smaller than the interlayer exchange coupling field) has a small effect, if any, on the energy of the synthetic antiferromagnet. Thus, the use of a synthetic antiferromagnet as the second synthetic antiferromagnet 624 can reduce and possibly eliminate stray field bias on the magnetization of the second synthetic antiferromagnet 624.

The various components and layers of the MTJ 600 can comprise the following materials. The antiferromagnet 616 can comprise chromium, a material comprising iridium and manganese (such as IrMn or IrMn₃), a material comprising iron and manganese (such as FeMn), a material comprising nickel and oxygen (such as NiO), hermatite (α-Fe₂O₃, a material comprising iron and oxygen), or another suitable antiferromagnetic material. Any of the ferromagnets of the synthetic antiferromagnets (e.g., 632, 636, 644, 648) can comprise cobalt, iron, a material comprising cobalt and iron (such as CoFe), a material comprising cobalt, iron, and boron (such as CoFeB), a material comprising iron and boron (such as FeB), a material comprising nickel and iron (such as permalloy), a material comprising iron and platinum (such as FePt), a material comprising cobalt and platinum (such as CoPt), a material comprising manganese and bismuth (such as MnBi), a material comprising nickel, manganese and antimony (such as NiMnSb), lanthanum strontium manganite (La₍₁₋ₓ₎Sr₍ₓ₎MnO₃, also referred to as LSMO, which is a material comprising lanthanum, strontium, manganese, and oxygen), yttrium iron garnet (Y₃Fe₂(FeO₄)₃, Y₃Fe₅O₁₂), chromium dioxide (CrO₂, which is a material comprising chromium and oxygen), Sr₂FeMoO₆ (which is a material comprising strontium, iron, molybdenum, and oxygen), iron(II,III) oxide (Fe₃O₄, which is a material comprising iron and oxygen), or another suitable ferromagnetic material.

In some embodiments, a ferromagnet of the synthetic antiferromagnets 620 and 624 can comprise a periodic multilayer structure comprising layers comprising cobalt alternating with layers comprising platinum or nickel. That is, a period of the periodic multilayer structure comprises a layer comprising cobalt and a layer comprising platinum or nickel.

In some embodiments, the ferromagnet of the synthetic antiferromagnet free layer 624 adjacent to the insulating layer 628 (e.g., ferromagnet 644) can comprise a layer comprising cobalt and platinum, a first layer comprising cobalt and a second layer comprising platinum, or a first layer comprising cobalt and a second layer comprising cobalt and platinum; and the other ferromagnet of the synthetic antiferromagnet free layer 624 (e.g., ferromagnet 648) can comprise a layer comprising cobalt and platinum, a first layer comprising cobalt and a second layer comprising platinum, or a first layer comprising cobalt and a second layer comprising cobalt and platinum. In other embodiments, the ferromagnet of the synthetic antiferromagnet free layer 624 adjacent to the insulating layer 628 can comprise permalloy and the other ferromagnet of the synthetic antiferromagnet free layer 624 can comprise cobalt.

The nonmagnetic layers (e.g., 640, 652) of the synthetic antiferromagnets 620 and 624 can comprise ruthenium, copper, platinum, tungsten, iridium, chromium, gold, or another suitable nonmagnetic material. The insulating layer 628 can comprise magnesium oxide (MgO, which is a material comprising magnesium and oxygen) or another suitable insulating material.

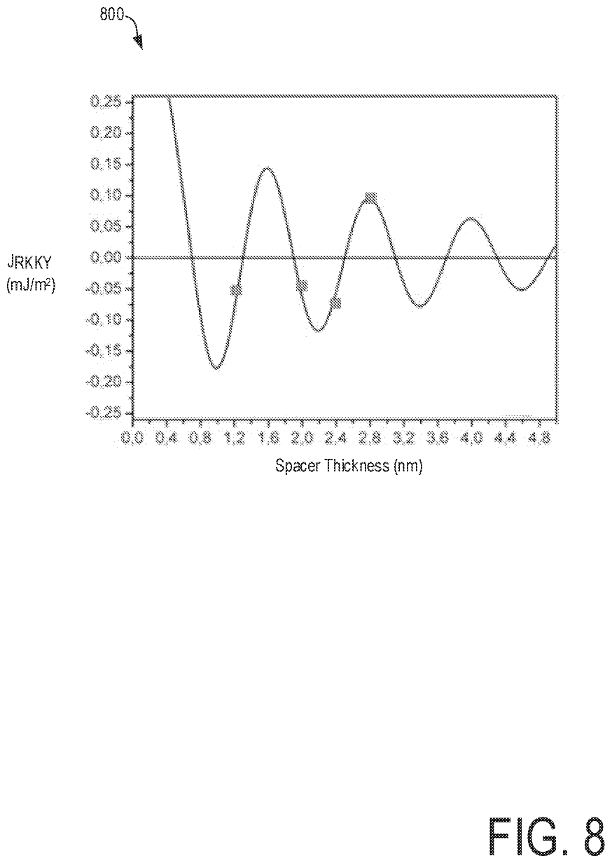

The amount of interlayer exchange coupling between the ferromagnets in the synthetic antiferromagnet free layer 624 is a function of the thickness of the nonmagnetic layer 652. FIG. 8 is a chart illustrating the dependency of interlayer exchange coupling (RKKY coupling, J_{RKKY}) on nonmagnetic layer (spacer) thickness for an example synthetic antiferromagnet. Chart 800 illustrates the dependency of interlayer exchange coupling for a synthetic antiferromagnet structure comprising a ruthenium spacer positioned between ferromagnets comprising cobalt and platinum on spacer thickness. The chart 800 illustrates that interlayer exchange coupling dependency on spacer thickness is an oscillating function (the ferromagnets are aligned in parallel (ferromagnetically) if J_{RKKY}>0 and antiparallel (antiferromagnetically) if J_{RKKY}<0). As a large negative exchange coupling between ferromagnets in a synthetic antiferromagnet in an MTJ is desirable to increase the rate at which random numbers can be generated (as will be discussed in further detail below), a spacer thickness corresponding to a minimum (or near a minimum) of the exchange coupling-spacer thickness curve can be chosen for a particular synthetic antiferromagnet structure.

Returning to FIG. 6, the electrode 604 can comprise a first conductive layer comprising ruthenium (Ru) and a second conductive layer comprising tantalum (Ta) positioned adjacent to the first conductive layer, the first conductive layer positioned adjacent to the antiferromagnet 616. The second electrode 608 can comprise a first conductive layer comprising tantalum (Ta), a second conductive layer comprising ruthenium (Ru) positioned adjacent to the first conductive layer, and a third conductive layer comprising tantalum (Ta) positioned adjacent to the second conductive layer. In other embodiments, the electrodes 604 and 608 can comprise other suitable sets of one or more conductive layers. The use of the same fill pattern in the figures for multiple components or layers does not mean the multiple components or layers must comprise the same materials. For example, with regard to FIG. 6, electrodes 604 and 608 can comprise the same or differential materials, the individual ferromagnets 632, 636, 644, and 648 can comprise the same or different materials, and the nonmagnetic layers 640 and 656 can comprise the same or different materials.

FIG. 7 illustrates a second example STT MTJ comprising a synthetic antiferromagnet free layer. The STT MTJ 700 comprises a first electrode 704 acting as a first terminal 770, a second electrode acting as a second terminal 774, an antiferromagnet layer 716, a first synthetic antiferromagnet 720, a second synthetic antiferromagnet 724 (synthetic antiferromagnet free layer), and an insulating layer 728. The reference layer 718 of the MTJ 700 comprises the antiferromagnet 716 and the second synthetic antiferromagnet 720. The components and layers of the MTJ 700 are arranged in the same manner as the corresponding components and layers as in the MTJ 600.

The first electrode 704 comprises a first conductive layer 702 comprising ruthenium and having a thickness of about 5 nm and a second conductive layer 706 comprising tantalum and having a thickness of about 2 nm. The antiferromagnet 716 comprises iridium and manganese and has a thickness of about 7 nm. The first synthetic antiferromagnet 720 comprises a first ferromagnet 732, a second ferromagnet 736, and a nonmagnetic layer 740 positioned between the ferromagnets 732 and 736. The first ferromagnet 732 comprises cobalt and iron and has a thickness of about 2.5 nm, the second ferromagnet 736 comprises cobalt, iron, and boron and has a thickness of about 2 nm, and the nonmagnetic layer 740 comprises ruthenium and has a thickness of about 0.9 nm. The insulating layer 728 comprises magnesium oxide (MgO) and has a thickness of about 1 nm. The second synthetic antiferromagnet 724 comprises a first ferromagnet 744, a second ferromagnet 748, and a nonmagnetic layer 756 positioned between the ferromagnets 744 and 748. The first ferromagnet 744 comprises cobalt, iron, and boron and has a thickness of about 1.5 nm. The second ferromagnet 748 also comprises cobalt, iron, and boron and has a thickness of about 1.5 nm. The nonmagnetic layer 756 comprises ruthenium and has a thickness of about 0.9 nm. The second electrode 708 comprises a first conductive layer 707 comprising tantalum and has a thickness of about 5 nm; a second conductive layer 709 positioned adjacent to the first conductive layer 707, the second conductive layer 709 comprising ruthenium and having a thickness of about 20 nm; and a third conductive layer 710 positioned adjacent to the second conductive layer 709, the third conductive layer 710 comprising tantalum and having a thickness of about 5 nm.

The MTJ 700 is located on a layer 750, which can be a substrate, such as a wafer comprising silicon or an interlayer dielectric (ILD) layer. An ILD can be any suitable nitride or oxide, such as silicon dioxide (SiO₂, which is a material that comprises silicon and oxygen), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂ which is a material that comprises silicon, oxygen, and hydrogen), and silicon nitride (Si₃N₄, which is a material that comprises silicon and nitrogen).

The set of layer thickness illustrated in FIG. 7 is just one example set of layer thicknesses. In other embodiments, one or more of the MTJ 700 layers can have a thickness different than that illustrated in FIG. 7. Additionally, in other embodiments, one or more of the components and layers of an STT MTJ can comprise different materials than those illustrated in FIG. 7.

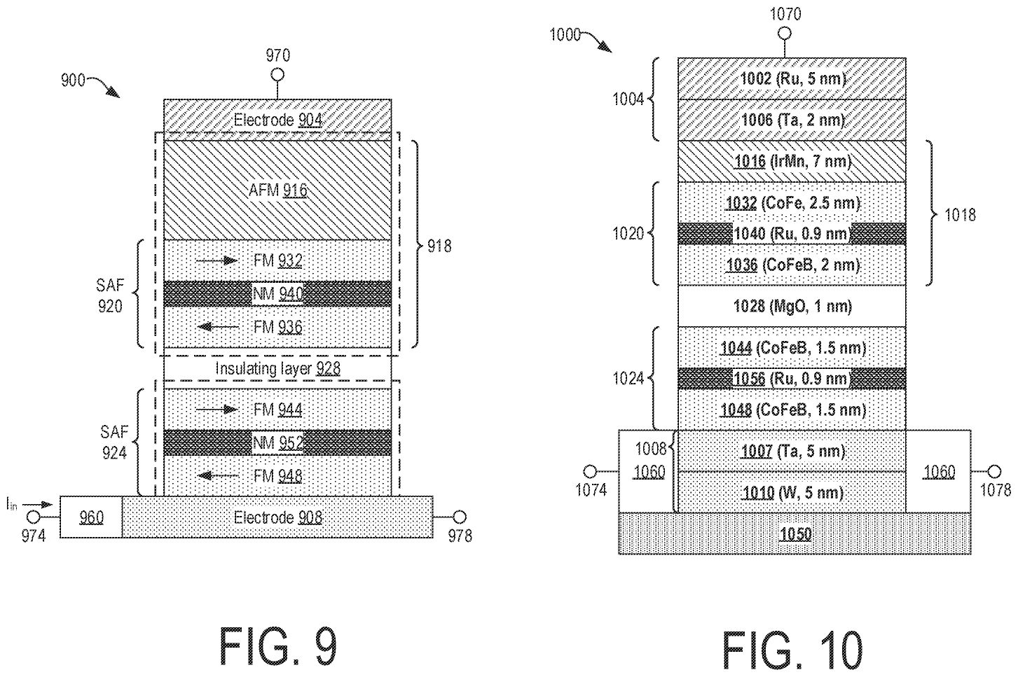

FIG. 9 illustrates a first example SOT MTJ comprising a synthetic antiferromagnet free layer. The structure of the spin-orbit torque (SOT) MTJ 900 is similar to that of STT MTJ 600, but with a spin-orbit torque electrode as one of the electrodes. The SOT MTJ 900 is a three-terminal device with a first electrode 904 acting as a first terminal 970 and second and third terminals 974 and 978 providing connections to a second spin-orbit torque electrode 908 for an in-plane current to pass through.

The SOT MTJ 900 comprises the first electrode 904, the SOT electrode 908, an antiferromagnet 916, a first synthetic antiferromagnet 920, a second synthetic antiferromagnet (synthetic antiferromagnet free layer) 924, and an insulating layer 928 positioned between the first synthetic antiferromagnet 920 and the second synthetic antiferromagnet 924. The antiferromagnet 916 positioned between the first electrode 904 and the first synthetic antiferromagnet 920 and the reference layer 918 of the MTJ 900 comprises the antiferromagnet 916 and the synthetic antiferromagnet 920. The first synthetic antiferromagnet 920 comprises a first ferromagnet 932, a second ferromagnet 936, and a nonmagnetic layer 940 positioned between the first ferromagnet 932 and the second ferromagnet 936. The synthetic antiferromagnet 924 comprises a third ferromagnet 944, a fourth ferromagnet 948, and a nonmagnetic layer 952 positioned between the third ferromagnet 944 and the fourth ferromagnet 948.

The various components and layers of the MTJ 900 can comprise the following materials. The antiferromagnet 916 can comprise chromium, a material comprising iridium and manganese (such as IrMn or IrMn₃), a material comprising iron and manganese (such as FeMn), a material comprising nickel and oxygen (such as NiO), hermatite (α-Fe₂O₃, a material comprising iron and oxygen), or another suitable antiferromagnetic material. Any of the ferromagnets of the synthetic antiferromagnets (e.g., 932, 936, 944, 948) can comprise cobalt, iron, a material comprising cobalt and iron (such as CoFe), a material comprising cobalt, iron, and boron (such as CoFeB), a material comprising iron and boron (such as FeB), a material comprising nickel and iron (such as permalloy), a material comprising iron and platinum (such as FePt), a material comprising cobalt and platinum (such as CoPt), a material comprising manganese and bismuth (such as MnBi), a material comprising nickel, manganese, and antimony (such as NiMnSb), lanthanum strontium manganite, yttrium iron garnet, chromium dioxide, Sr₂FeMoO₆, iron(II,III) oxide, or another suitable ferromagnetic material.

In some embodiments, a ferromagnet of the synthetic antiferromagnets 920 and 924 can comprise a periodic multilayer structure comprising layers comprising cobalt alternating with layers comprising platinum or nickel. That is, a period of the periodic multilayer structure comprises a layer comprising cobalt and a layer comprising platinum or nickel.

In some embodiments, the ferromagnet of the synthetic antiferromagnet free layer 924 adjacent to the insulating layer 928 (e.g., ferromagnet 944) can comprise a layer comprising cobalt and platinum, a first layer comprising cobalt and a second layer comprising platinum, or a first layer comprising cobalt and a second layer comprising cobalt and platinum; and the other ferromagnet of the synthetic antiferromagnet free layer 924 (e.g., ferromagnet 948) can comprise a layer comprising cobalt and platinum, a first layer comprising cobalt and a second layer comprising platinum, or a first layer comprising cobalt and a second layer comprising cobalt and platinum. In other embodiments, the ferromagnet of the synthetic antiferromagnet free layer 924 adjacent to the insulating layer 928 can comprise permalloy and the other ferromagnet of the synthetic antiferromagnet free layer 924 can comprise cobalt.

The nonmagnetic layers (e.g., 940, 952) of the synthetic antiferromagnets 920 and 924 can comprise ruthenium, copper, platinum, tungsten, iridium, chromium, gold, or another suitable nonmagnetic material. The insulating layer 928 can comprise magnesium oxide (MgO, which is a material comprising magnesium and oxygen) or another suitable insulating material.

The electrode 904 comprises a first conductive layer positioned adjacent to the antiferromagnet 916 comprising ruthenium and a second conductive layer comprising tantalum positioned adjacent to the first conductive layer. The spin-orbit torque electrode 908 comprises a first conductive layer comprising tantalum positioned adjacent to a second conductive layer comprising tungsten (W). In other embodiments, the electrodes 904 and 908 can comprise other suitable sets of one or more conductive layers. Nonmagnetic conductive trace portions 960 are positioned horizontally adjacent to the SOT electrode 908 (the nonmagnetic conductive trace portions 960 being positioned horizontally adjacent to the SOT electrode 908 relative to the vertically adjacent positioning of the SOT electrode 908 to the synthetic antiferromagnet 924).

A current can be applied across the terminals 974 and 978 that causes an in-plane current to pass through the spin-orbit torque electrode 908. The in-plane current causes a polarized spin current to be injected into the free layer ferromagnet 948, which exerts enough of a spin torque on the free layer ferromagnet 948 to influence its magnetization. The in-plane current can bias the distribution of random numbers generated by a p-bit of which the MTJ 900 is a part.

FIG. 10 illustrates a second example SOT MTJ comprising an MTJ with a synthetic antiferromagnet free layer. The SOT MTJ 1000 comprises a first electrode 1004 acting as a first terminal 1070 and second and third terminals 1074 and 1078 providing connections to a second spin-orbit torque electrode 1008 to allow for the application of an in-plane current to pass through the SOT electrode 1008. The SOT MTJ 1000 comprises first and second electrodes 1004 and 1008, an antiferromagnet 1016, a first synthetic antiferromagnet 1020, a second synthetic antiferromagnet 1024, and an insulating layer 1028. The reference layer 1018 of the MTJ 1000 comprises the antiferromagnet 1016 and the first synthetic antiferromagnet 1020. The components and layers of the MTJ 1000 are arranged in the same manner as the corresponding components and layers in the MTJ 900.

The first electrode 1004 comprises a first conductive layer 1002 comprising ruthenium and having a thickness of about 5 nm and a second conductive layer 1006 comprising tantalum and having a thickness of about 2 nm. The antiferromagnet 1016 comprises iridium and manganese and has a thickness of about 7 nm. The first synthetic antiferromagnet 1020 comprises a first ferromagnet 1032, a second ferromagnet 1036, and a nonmagnetic layer 1040 positioned between the ferromagnets 1032 and 1036. The first ferromagnet 1032 comprises cobalt and iron and has a thickness of about 2.5 nm, the second ferromagnet 1036 comprises cobalt, iron, and boron and has a thickness of about 2 nm, and the nonmagnetic layer 1040 comprises ruthenium and has a thickness of about 0.9 nm. The insulating layer 1028 comprises magnesium oxide (MgO) and has a thickness of about 1.0 nm. The second synthetic antiferromagnet 1024 comprises a first ferromagnet 1044, a second ferromagnet 1048, and a nonmagnetic layer 1056 positioned between the ferromagnets 1044 and 1048. The first ferromagnet 1044 comprises cobalt, iron, and boron and has a thickness of about 1.5 nm. The second ferromagnet 1048 also comprises cobalt, iron, and boron and has a thickness of about 1.5 nm. The nonmagnetic layer 1056 comprises ruthenium and has a thickness of about 0.9 nm. The second electrode 1008 comprises a first conductive layer 1007 comprising tantalum and having a thickness of about 5 nm and a second conductive layer 1010 positioned adjacent to the first conductive layer 1007, the second conductive layer 1007 comprising tungsten and having a thickness of about 5 nm.

Nonmagnetic conductive trace portions 1060 are positioned horizontally adjacent to the SOT electrode 1008 (the nonmagnetic conductive trace portions 1060 being positioned horizontally adjacent to the SOT electrode 1008 relative to the vertically adjacent positioning of the SOT electrode 1008 to synthetic antiferromagnet 1024).

The nonmagnetic conductive traces portions 960 and 1060 can be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals. The nonmagnetic conductive trace portions 960 and 1060 can be part of a line of a metal layer in a metallization stack in an integrated circuit component.

The MTJ 1000 is located on a layer 1050, which can be a substrate or an ILD layer, with the substrate or ILD layer comprising any of the materials that can comprise the layer 850 discussed above in regard to FIG. 8. The set of layer thickness illustrated in FIG. 10 is just one example set of layer thicknesses. In other embodiments, one or more of the MTJ 1000 layers can have a thickness different than that illustrated in FIG. 10. Additionally, in other embodiments, one or more of the components or layers of an STT MTJ can comprise materials different than those illustrated in FIG. 10.

The MTJs 600, 700, 900, and 1000 can be embedded in a metallization stack in an integrated circuit component and the electrodes of the MTJs 600, 700, 900, and 1000 can be positioned adjacent to a conductive trace that is a line of a metal layer in a metallization stack. For example, the electrode 604 of the STT MTJ 600 can be positioned adjacent to a conductive trace that is a Metal 3 (“M3”) line in a metallization stack and the electrode 608 of the MTJ 600 can be positioned adjacent to a conductive trace that is a Metal 2 (“M2”) line in a metallization stack. In another example, electrode 904 of the SOT MTJ 900 can be positioned adjacent to a conductive trace that is a Metal 4 (“M4”) line in a metallization stack and the SOT electrode 908 of the SOT MTJ 900 can be positioned adjacent to conductive trace portions that are M3 lines in a metallization stack.

The MTJs described herein can be fabricated using back end of line (BEOL) manufacturing techniques used in CMOS manufacturing technologies. As such, a wafer upon which the MTJs described herein are fabricated or an integrated circuit component comprising such MTJs can comprise other types of devices, such as electronic transistors (transistors such as CMOS transistors that operate through control of the flow of electric current and that do not rely upon the switching of the magnetization of a layer or component for operation) and/or magnetoelectric spin-orbit (MESO) devices that use magnetoelectric switching to convert an input voltage/charge into a magnetic spin state (e.g., charge-to-spin conversion) and further uses spin-orbit transduction to convert the magnetic spin state back into an output charge/voltage (e.g., spin-to-charge conversion).

Conductive traces in a metallization stack can be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals. The nonmagnetic portions can be part of a line of a metallization layer in a metallization stack in an integrated circuit component.

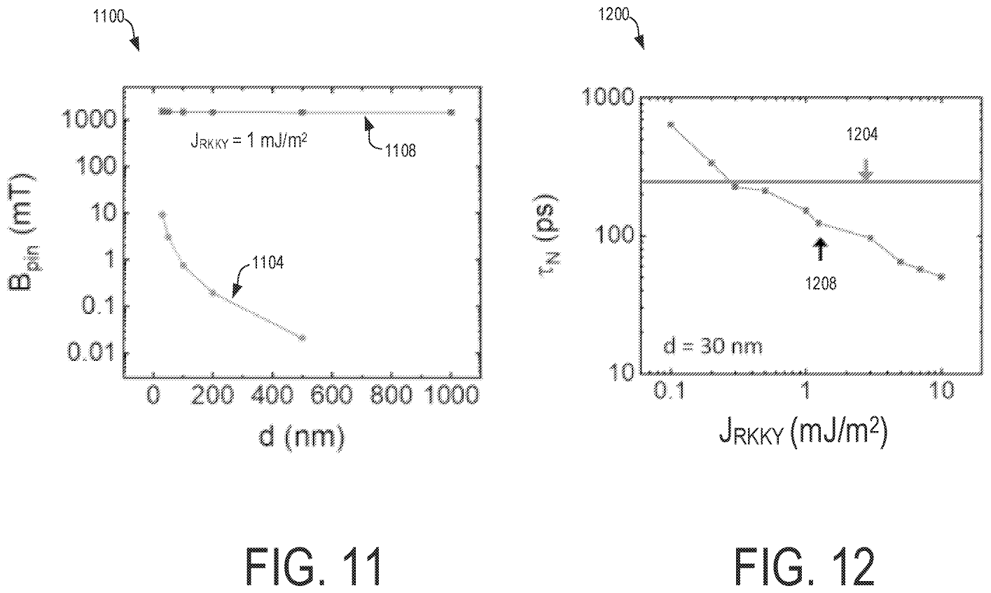

FIG. 11 illustrates simulated external magnetic pinning field strength for a ferromagnet as a function of structure size. The chart 1100 shows the dependency of Bₚᵢₙ, a magnetic field sufficient to pin the average magnetization of a ferromagnet to 90% of its saturation value, on the diameter of a cylindrically-shaped ferromagnet or synthetic antiferromagnets for a J_{RKKY} of 1 mJ/m². The chart 1100 is based on solutions to the Landau-Lifshitz-Gilbert (LLG) equation in the presence of thermal noise. Curve 1104 shows Bₚᵢₙ vs. structure diameter for a single-layer ferromagnet and curve 1108 shows the same relationship for a corresponding synthetic antiferromagnet structure. As a larger Bₚᵢₙ implies that a ferromagnet is more robust to unwanted external magnetic fields, chart 1100 shows that the synthetic antiferromagnet structure is more than 100 times more robust against external magnetic field than a comparable single-layer ferromagnet. As the Bₚᵢₙ for a synthetic antiferromagnet scales roughly linearly with its interlayer exchange coupling (J_{RKKY}), reducing the exchange coupling by a factor of 10 (J_{RKKY} of 0.1 mJ/m²) would result in a synthetic antiferromagnet structure that is still more than 10 times more robust against external magnetic fields compared to a single-layer ferromagnet.

FIG. 12 illustrates simulated autocorrelation time of the magnetization fluctuation in single-layer ferromagnet and synthetic antiferromagnet structures. Lines 1204 and 1208 in graph 1200 show the autocorrelation time of single-layer ferromagnet and synthetic antiferromagnet structures with a diameter of 30 nm, respectively. Graph 1200 shows that the speed of magnetization fluctuation in a synthetic antiferromagnet structure increases with increased interlayer exchange coupling (J_{RKKY}). The autocorrelation time of the magnetization fluctuation, T_{N}, becomes smaller for increasing J_{RKKY} for synthetic antiferromagnet structures, illustrating that the interlayer exchanging coupling is an independent parameter that can be tuned to adjust the magnetization fluctuation speed. For a single-layer ferromagnet, the magnetization fluctuation depends on the demagnetization field H_{D} and thus is a constant in graph 1200. It can be seen that the synthetic antiferromagnet structure has speed advantages over a single-layer ferromagnet for J_{RKKY}>0.3 mJ/m². The simulated synthetic antiferromagnet structure comprised two identical ferromagnet, with the individual ferromagnets having a volume equal to that of the simulated single-layer ferromagnet. Therefore, the total volume of the synthetic antiferromagnet structure is twice that of the single-layer ferromagnet. If the volume of the synthetic antiferromagnet were reduced by half to match that of the single-layer ferromagnet, the line 1208 would shift downward and make the speed advantage of synthetic antiferromagnets over a single-layer ferromagnet even more prominent.

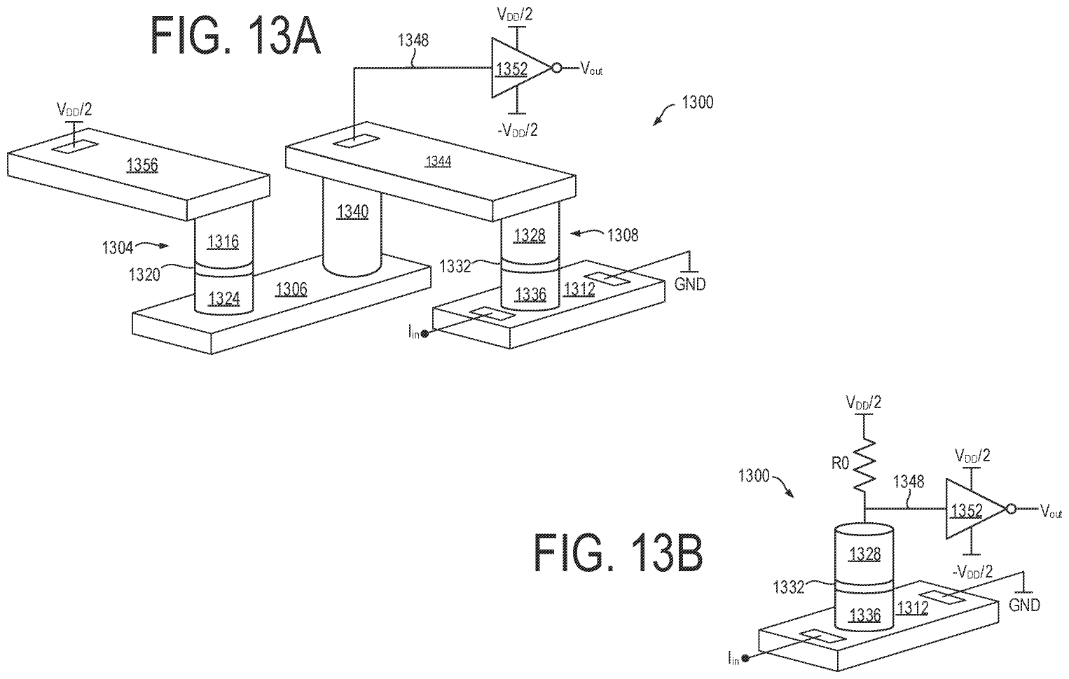

FIGS. 13A-13B illustrate an example p-bit comprising an MTJ operating as a reference resistor. FIG. 13A illustrates the physical arrangement and connections of a p-bit 1300 and FIG. 13B illustrates an equivalent schematic. P-bit 1300 comprises a SOT MTJ 1304 acting as a reference resistor connected in series with a second SOT MTJ 1308. The MTJ 1304 comprises a synthetic antiferromagnet reference layer 1316, an insulating layer 1320, a synthetic antiferromagnet free layer 1324, and an STO bottom electrode 1306. The second MTJ 1308 comprises a synthetic antiferromagnet reference layer 1328, an insulating layer 1332, a synthetic antiferromagnet free layer 1336 and a SOT bottom electrode 1312. The MTJs 1304 and 1308 are connected in series with the SOT bottom electrode 1306, a via 1340, and a conductive trace 1344 providing an electrically conductive path from the MTJ 1304 to the MTJ 1308.

An intermediate node 1348 between the MTJs 1304 and 1308 is connected to the input of an inverter 1352 to generate the output of the p-bit. The inverter 1352 is connected to V_{DD}/2 and −V_{DD}/2 power signals. The resistance of the MTJ load resistor (R0) can be the average resistance of the MTJ 1304. A top electrode of the MTJ 1304 (not shown) is connected to V_{DD}/2 by a conductive trace 1356. The distribution of random numbers generated by the p-bit 1300 is controlled by an in-plane input current (Iᵢₙ) that flows through the bottom SOT electrode 1312 of the second MTJ 1308.

The use of an MTJ with a synthetic antiferromagnet free layer as a reference resistor in a p-bit provides a reference resistor whose resistance value and resistance value variation (due to manufacturing and operation condition variability) more closely matches that of the MTJ that provides p-bit tunability. That is, MTJ “pillars” comprising a synthetic antiferromagnet free layer can be used as physical building blocks for building p-bits and other probabilistic computing devices. Further, using an MTJ device as the reference resistor in a p-bit can counter the unwanted effects of current bias on MTJs. With the two MTJs connected in series, the same read current can pass through the MTJs 1304 and 1308 when the p-bit is being read (e.g., when the V_{DD}/2 and −V_{DD}/2 signals are applied to the p-bit), biasing the two MTJs similarly, which can act to nullify the effects of current bias on random numbers generated by the p-bit.

In probabilistic computing, the input voltage to one p-bit can be the weighted sum of the voltage outputs of other p-bits. To achieve this functionality in CMOS manufacturing technologies, operational amplifier-based summing amplifiers can be used for voltage addition. As the SOT MTJ-based p-bits disclosed herein have a low impedance input defined by the SOT bottom electrode, voltage addition operations can be implemented using SOT MTJ-based p-bits without the use of operational amplifiers.

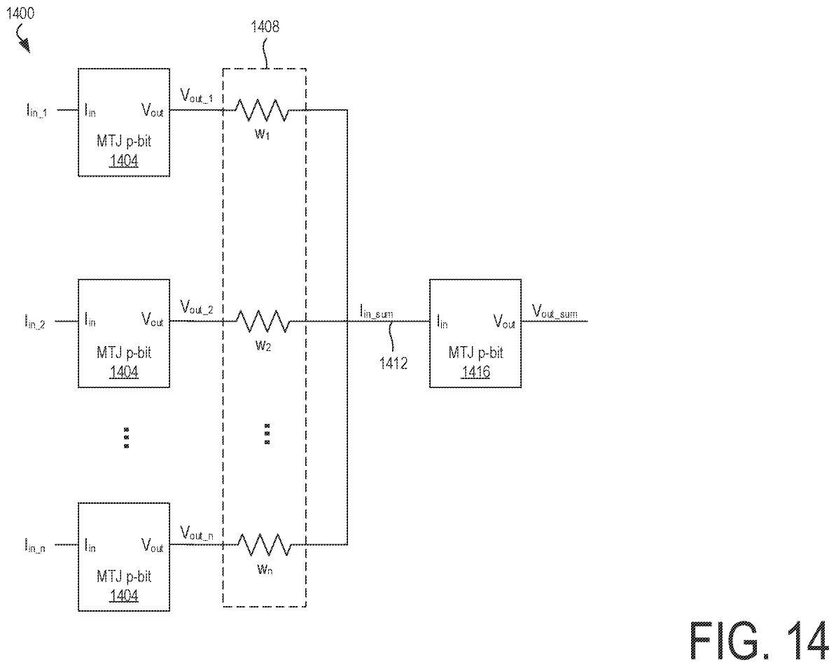

FIG. 14 illustrates an example weighted summing circuit utilizing SOT MTJ-based p-bits. The circuit 1400 comprises input p-bits 1404 whose voltage outputs are fed into a weighted resistor matrix 1408 to generate an input 1412 for an output p-bit 1416. The weighted matrix 1408 can be formed by an analog RRAM (resistive RAM) array, a multilevel MRAM (magnetic RAM) array, or another suitable resistor bank implementation. Assuming a low resistance of the SOT bottom electrode layer of the output p-bit 1416, the current flowing into the input terminal (Iᵢₙ) of the output p-bit is I_{IN_SUM}=Σᵢ(wᵢ*V_{OUT,i}), which can be a desired weighted sum.

The MTJs and the probabilistic computing devices described herein can be used in any processor unit, integrated circuit component, or computing system described or referenced herein. The MTJs and the probabilistic computing devices described herein, along with any processor unit, integrated circuit component, or computing system described or referenced herein may be referred to as an apparatus. The MTJs and probabilistic computing devices can be fabricated as part of an integrated circuit structure. The integrated circuit structure can comprise a die substrate, such as a wafer comprising silicon, and one or more interconnect or metal layers. An electrode of a probabilistic computing device can connect to lines of an interconnect or metal layer by a via or by being positioned adjacent to a line of a metal layer. An integrated circuit structure comprising any of the MTJs or probabilistic computing devices described herein can comprise other types of devices, such as electronic transistors (transistors such as CMOS transistors that operate through control of the flow of electric current and that do not rely upon the switching of the magnetization of a layer or component for operation) and/or magnetoelectric spin-orbit (MESO) devices that use magnetoelectric switching to convert an input voltage/charge into a magnetic spin state (e.g., charge-to-spin conversion) and further uses spin-orbit transduction to convert the magnetic spin state back into an output charge/voltage (e.g., spin-to-charge conversion). An integrated circuit component comprising one or more of the MTJs or probabilistic computing devices described herein can be attached to a printed circuit board. In some embodiments, one or more additional integrated circuit components can be attached to the circuit board. In some embodiments, the printed circuit board and the integrated circuit component can be located in a computing device that comprises a housing that encloses the printed circuit board and the integrated circuit component.

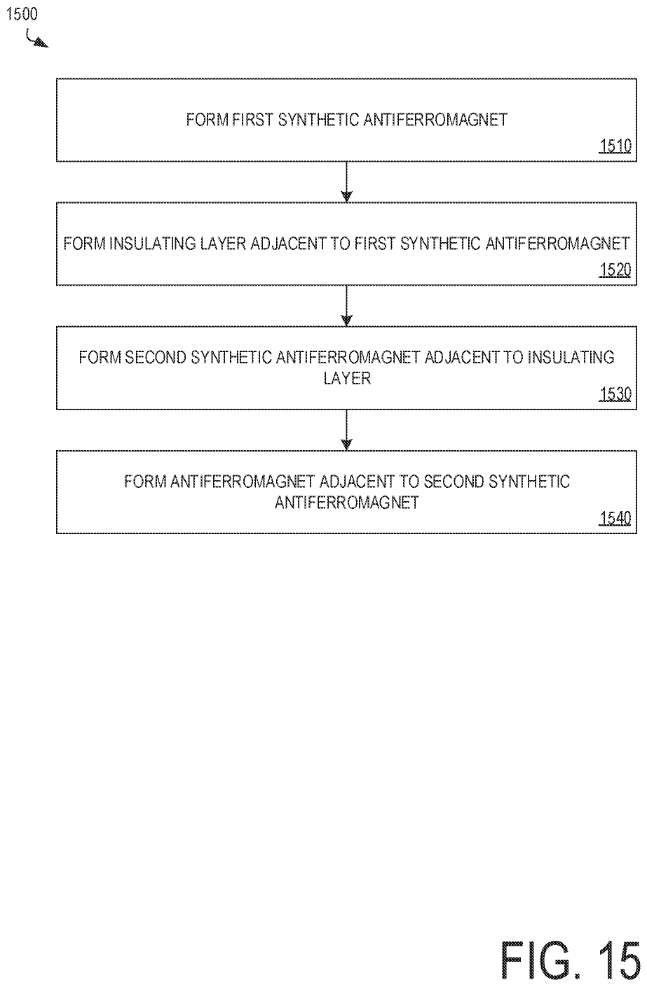

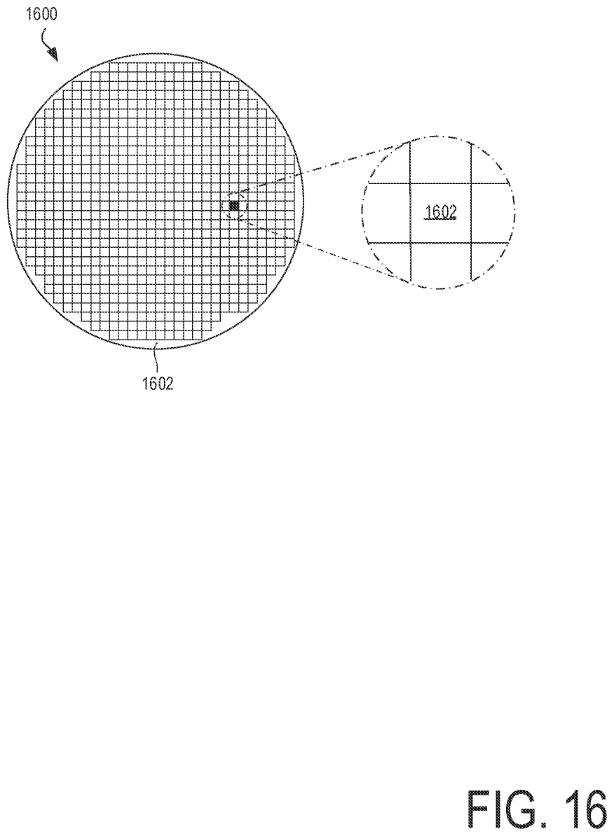

FIG. 15 is an example method of forming an MTJ comprising synthetic antiferromagnets. At 1510 in the method 1500, a first synthetic antiferromagnet is formed. At 1520, an insulating layer adjacent to the first synthetic antiferromagnet is formed. At 1530, a second synthetic antiferromagnet adjacent to the insulating layer is formed. At 1540, an antiferromagnet adjacent to the second synthetic antiferromagnet is formed.

In some embodiments, the method 1500 can comprise additional elements. For example, the method 1500 can further comprise forming a first electrode prior to forming the first synthetic antiferromagnet, the first synthetic antiferromagnet formed adjacent to the first electrode; and forming a second electrode adjacent to the antiferromagnet. In another example, the method 1500 can further comprise etching a hole in an interlayer dielectric prior to forming the first synthetic antiferromagnet, the first synthetic antiferromagnet, the insulating layer, the second synthetic antiferromagnet, and the antiferromagnet being formed in the hole.

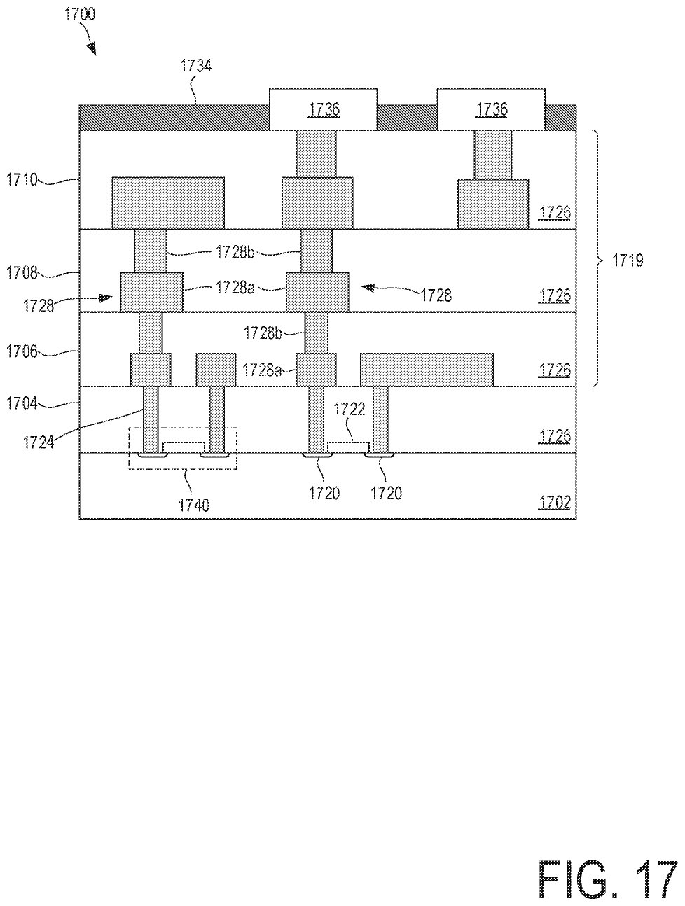

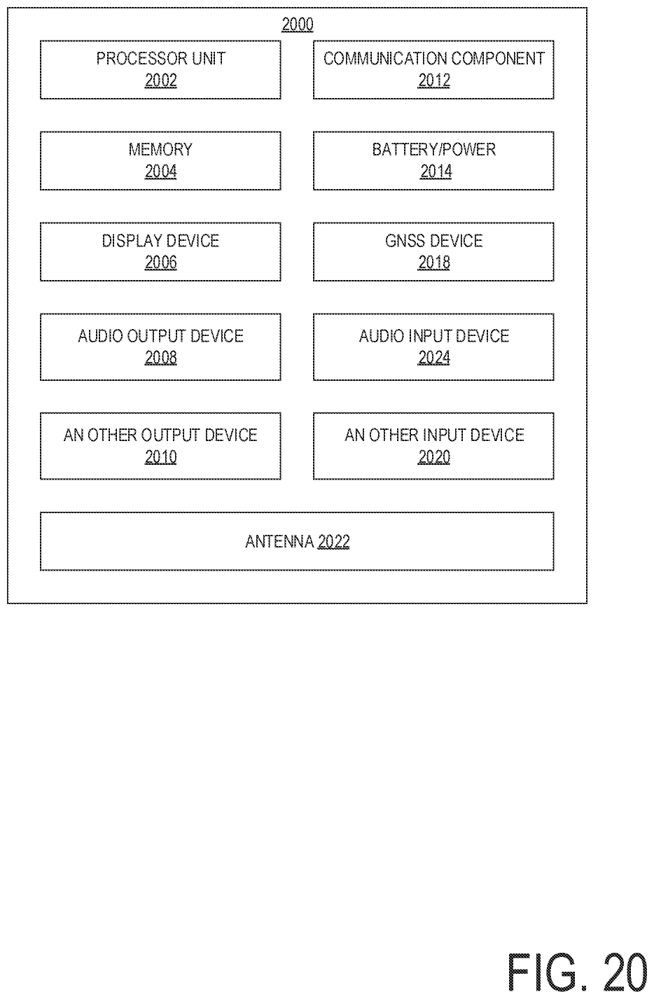

FIG. 16 is a top view of a wafer 1600 and dies 1602 that may include any of the MTJs or probabilistic computing devices disclosed herein. The wafer 1600 may be composed of semiconductor material and may include one or more dies 1602 having integrated circuit structures formed on a surface of the wafer 1600. The individual dies 1602 may be a repeating unit of an integrated circuit product that includes any suitable integrated circuit. After the fabrication of the semiconductor product is complete, the wafer 1600 may undergo a singulation process in which the dies 1602 are separated from one another to provide discrete “chips” of the integrated circuit product. The die 1602 may include one or more transistors (e.g., some of the transistors 1740 of FIG. 17, discussed below), supporting circuitry to route electrical signals to the transistors, passive components (e.g., signal traces, resistors, capacitors, or inductors), and/or any other integrated circuit components. In some embodiments, the wafer 1600 or the die 1602 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1602. For example, a memory array formed by multiple memory devices may be formed on a same die 1602 as a processor unit (e.g., the processor unit 2002 of FIG. 20) or other logic that is configured to store information in the memory devices or execute instructions stored in the memory array. Various ones of the assemblies disclosed herein may be manufactured using a die-to-wafer assembly technique in which some dies are attached to a wafer 1600 that include others of the dies, and the wafer 1600 is subsequently singulated.

FIG. 17 is a cross-sectional side view of an integrated circuit device 1700 that may be included in any of the integrated circuit components disclosed herein. One or more of the integrated circuit devices 1700 may be included in one or more dies 1602 (FIG. 16). The integrated circuit device 1700 may be formed on a die substrate 1702 (e.g., the wafer 1600 of FIG. 16) and may be included in a die (e.g., the die 1602 of FIG. 16). The die substrate 1702 may be a semiconductor substrate composed of semiconductor material systems including, for example, n-type or p-type materials systems (or a combination of both). The die substrate 1702 may include, for example, a crystalline substrate formed using a bulk silicon or a silicon-on-insulator (SOI) substructure. In some embodiments, the die substrate 1702 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an integrated circuit device 1700 may be used. The die substrate 1702 may be part of a singulated die (e.g., the dies 1602 of FIG. 16) or a wafer (e.g., the wafer 1600 of FIG. 16).

The integrated circuit device 1700 may include one or more device layers 1704 disposed on the die substrate 1702. The device layer 1704 may include features of one or more transistors 1740 (e.g., metal oxide semiconductor field-effect transistors (MOSFETs)) formed on the die substrate 1702. The transistors 1740 may include, for example, one or more source and/or drain (S/D) regions 1720, a gate 1722 to control current flow between the S/D regions 1720, and one or more S/D contacts 1724 to route electrical signals to/from the S/D regions 1720. The transistors 1740 may include additional features not depicted for the sake of clarity, such as device isolation regions, gate contacts, and the like. The transistors 1740 are not limited to the type and configuration depicted in FIG. 17 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

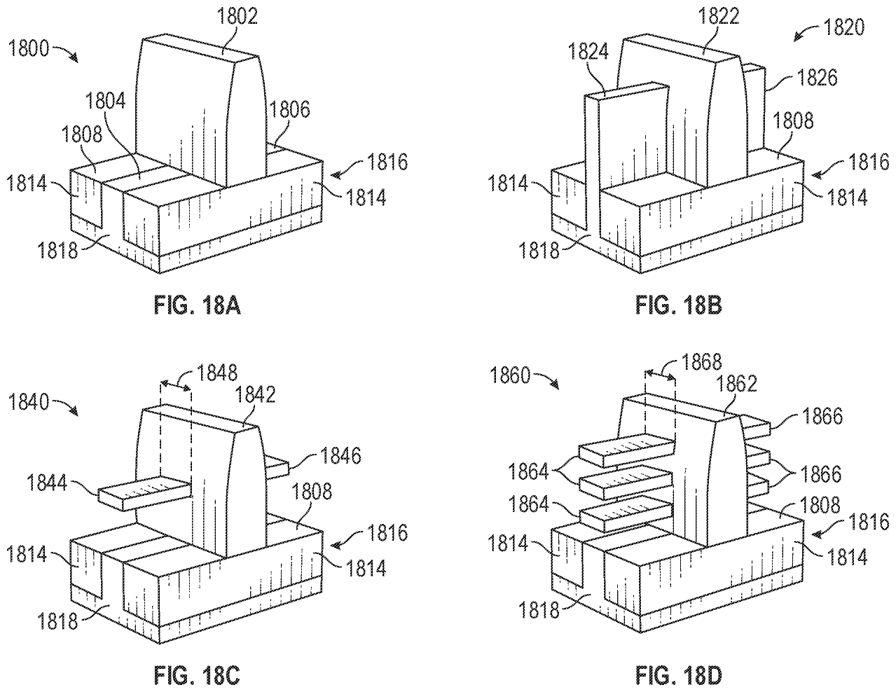

FIGS. 18A-18D are simplified perspective views of example planar, FinFET, gate-all-around, and stacked gate-all-around transistors. The transistors illustrated in FIGS. 18A-18D are formed on a substrate 1816 having a surface 1808. Isolation regions 1814 separate the source and drain regions of the transistors from other transistors and from a bulk region 1818 of the substrate 1816.

FIG. 18A is a perspective view of an example planar transistor 1800 comprising a gate 1802 that controls current flow between a source region 1804 and a drain region 1806. The transistor 1800 is planar in that the source region 1804 and the drain region 1806 are planar with respect to the substrate surface 1808.

FIG. 18B is a perspective view of an example FinFET transistor 1820 comprising a gate 1822 that controls current flow between a source region 1824 and a drain region 1826. The transistor 1820 is non-planar in that the source region 1824 and the drain region 1826 comprise “fins” that extend upwards from the substrate surface 1828. As the gate 1822 encompasses three sides of the semiconductor fin that extends from the source region 1824 to the drain region 1826, the transistor 1820 can be considered a tri-gate transistor. FIG. 18B illustrates one S/D fin extending through the gate 1822, but multiple S/D fins can extend through the gate of a FinFET transistor.

FIG. 18C is a perspective view of a gate-all-around (GAA) transistor 1840 comprising a gate 1842 that controls current flow between a source region 1844 and a drain region 1846. The transistor 1840 is non-planar in that the source region 1844 and the drain region 1846 are elevated from the substrate surface 1828.

FIG. 18D is a perspective view of a GAA transistor 1860 comprising a gate 1862 that controls current flow between multiple elevated source regions 1864 and multiple elevated drain regions 1866. The transistor 1860 is a stacked GAA transistor as the gate controls the flow of current between multiple elevated S/D regions stacked on top of each other. The transistors 1840 and 1860 are considered gate-all-around transistors as the gates encompass all sides of the semiconductor portions that extends from the source regions to the drain regions. The transistors 1840 and 1860 can alternatively be referred to as nanowire, nanosheet, or nanoribbon transistors depending on the width (e.g., widths 1848 and 1868 of transistors 1840 and 1860, respectively) of the semiconductor portions extending through the gate.

Returning to FIG. 17, a transistor 1740 may include a gate 1722 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1740 along the source-channel-drain direction, the gate electrode may consist of a U-shaped structure that includes a bottom portion substantially parallel to the surface of the die substrate 1702 and two sidewall portions that are substantially perpendicular to the top surface of the die substrate 1702. In other embodiments, at least one of the metal layers that form the gate electrode may simply be a planar layer that is substantially parallel to the top surface of the die substrate 1702 and does not include sidewall portions substantially perpendicular to the top surface of the die substrate 1702. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of individual transistors 1740. The S/D regions 1720 may be formed using an implantation/diffusion process or an etching/deposition process, for example. In the former process, dopants such as boron, aluminum, antimony, phosphorous, or arsenic may be ion-implanted into the die substrate 1702 to form the S/D regions 1720. An annealing process that activates the dopants and causes them to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1720 may be formed using one or more alternate semiconductor materials such as germanium or a group III-V material or alloy. In further embodiments, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more interconnect layers disposed on the device layer 1704 (illustrated in FIG. 17 as interconnect layers 1706-1710). For example, electrically conductive features of the device layer 1704 (e.g., the gate 1722 and the S/D contacts 1724) may be electrically coupled with the interconnect structures 1728 of the interconnect layers 1706-1710. The one or more interconnect layers 1706-1710 may form a metallization stack (also referred to as an “ILD stack”) 1719 of the integrated circuit device 1700.

The interconnect structures 1728 may be arranged within the interconnect layers 1706-1710 to route electrical signals according to a wide variety of designs; in particular, the arrangement is not limited to the particular configuration of interconnect structures 1728 depicted in FIG. 17. Although a particular number of interconnect layers 1706-1710 is depicted in FIG. 17, embodiments of the present disclosure include integrated circuit devices having more or fewer interconnect layers than depicted.

In some embodiments, the interconnect structures 1728 may include lines 1728a and/or vias 1728b filled with an electrically conductive material such as a metal. The lines 1728a may be arranged to route electrical signals in a direction of a plane that is substantially parallel with a surface of the die substrate 1702 upon which the device layer 1704 is formed. For example, the lines 1728a may route electrical signals in a direction in and out of the page and/or in a direction across the page from the perspective of FIG. 17. The vias 1728b may be arranged to route electrical signals in a direction of a plane that is substantially perpendicular to the surface of the die substrate 1702 upon which the device layer 1704 is formed. In some embodiments, the vias 1728b may electrically couple lines 1728a of different interconnect layers 1706-1710 together.

The interconnect layers 1706-1710 may include a dielectric material 1726 disposed between the interconnect structures 1728, as shown in FIG. 17. In some embodiments, dielectric material 1726 disposed between the interconnect structures 1728 in different ones of the interconnect layers 1706-1710 may have different compositions; in other embodiments, the composition of the dielectric material 1726 between different interconnect layers 1706-1710 may be the same. The device layer 1704 may include a dielectric material 1726 disposed between the transistors 1740 and a bottom layer of the metallization stack as well. The dielectric material 1726 included in the device layer 1704 may have a different composition than the dielectric material 1726 included in the interconnect layers 1706-1710; in other embodiments, the composition of the dielectric material 1726 in the device layer 1704 may be the same as a dielectric material 1726 included in any one of the interconnect layers 1706-1710.

A first interconnect layer 1706 (referred to as Metal 1 or “M1”) may be formed directly on the device layer 1704. In some embodiments, the first interconnect layer 1706 may include lines 1728a and/or vias 1728b, as shown. The lines 1728a of the first interconnect layer 1706 may be coupled with contacts (e.g., the S/D contacts 1724) of the device layer 1704. The vias 1728b of the first interconnect layer 1706 may be coupled with the lines 1728a of a second interconnect layer 1708.

The second interconnect layer 1708 (referred to as Metal 2 or “M2”) may be formed directly on the first interconnect layer 1706. In some embodiments, the second interconnect layer 1708 may include via 1728b to couple the lines 1728 of the second interconnect layer 1708 with the lines 1728a of a third interconnect layer 1710. Although the lines 1728a and the vias 1728b are structurally delineated with a line within individual interconnect layers for the sake of clarity, the lines 1728a and the vias 1728b may be structurally and/or materially contiguous (e.g., simultaneously filled during a dual-damascene process) in some embodiments.

The third interconnect layer 1710 (referred to as Metal 3 or “M3”) (and additional interconnect layers, as desired) may be formed in succession on the second interconnect layer 1708 according to similar techniques and configurations described in connection with the second interconnect layer 1708 or the first interconnect layer 1706. In some embodiments, the interconnect layers that are “higher up” in the metallization stack 1719 in the integrated circuit device 1700 (i.e., farther away from the device layer 1704) may be thicker that the interconnect layers that are lower in the metallization stack 1719, with lines 1728a and vias 1728b in the higher interconnect layers being thicker than those in the lower interconnect layers.

The integrated circuit device 1700 may include a solder resist material 1734 (e.g., polyimide or similar material) and one or more conductive contacts 1736 formed on the interconnect layers 1706-1710. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to external devices. For example, solder bonds may be formed on the one or more conductive contacts 1736 to mechanically and/or electrically couple an integrated circuit die including the integrated circuit device 1700 with another component (e.g., a printed circuit board). The integrated circuit device 1700 may include additional or alternate structures to route the electrical signals from the interconnect layers 1706-1710; for example, the conductive contacts 1736 may include other analogous features (e.g., posts) that route the electrical signals to external components.

In some embodiments in which the integrated circuit device 1700 is a double-sided die, the integrated circuit device 1700 may include another metallization stack (not shown) on the opposite side of the device layer(s) 1704. This metallization stack may include multiple interconnect layers as discussed above with reference to the interconnect layers 1706-1710, to provide conductive pathways (e.g., including conductive lines and vias) between the device layer(s) 1704 and additional conductive contacts (not shown) on the opposite side of the integrated circuit device 1700 from the conductive contacts 1736.

In other embodiments in which the integrated circuit device 1700 is a double-sided die, the integrated circuit device 1700 may include one or more through silicon vias (TSVs) through the die substrate 1702; these TSVs may make contact with the device layer(s) 1704, and may provide conductive pathways between the device layer(s) 1704 and additional conductive contacts (not shown) on the opposite side of the integrated circuit device 1700 from the conductive contacts 1736. In some embodiments, TSVs extending through the substrate can be used for routing power and ground signals from conductive contacts on the opposite side of the integrated circuit device 1700 from the conductive contacts 1736 to the transistors 1740 and any other components integrated into the die 1700, and the metallization stack 1719 can be used to route I/O signals from the conductive contacts 1736 to transistors 1740 and any other components integrated into the die 1700.

Multiple integrated circuit devices 1700 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

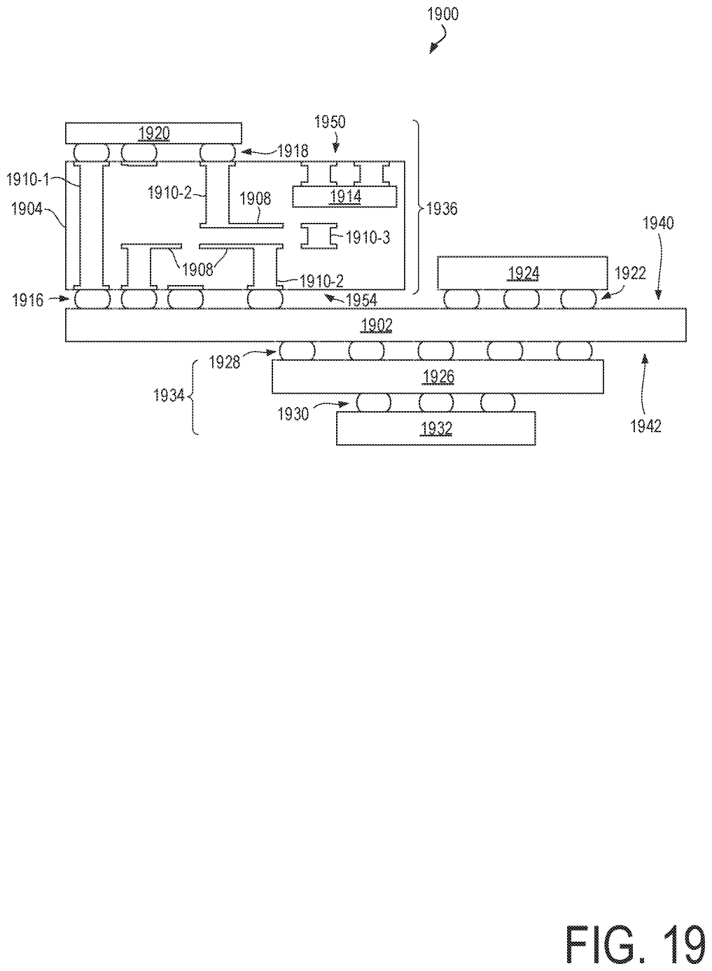

FIG. 19 is a cross-sectional side view of an integrated circuit device assembly 1900. The integrated circuit device assembly 1900 includes a number of components disposed on a circuit board 1902 (which may be a motherboard, system board, mainboard, etc.). The integrated circuit device assembly 1900 includes components disposed on a first face 1940 of the circuit board 1902 and an opposing second face 1942 of the circuit board 1902; generally, components may be disposed on one or both faces 1940 and 1942.

In some embodiments, the circuit board 1902 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1902. In other embodiments, the circuit board 1902 may be a non-PCB substrate. The integrated circuit device assembly 1900 illustrated in FIG. 19 includes a package-on-interposer structure 1936 coupled to the first face 1940 of the circuit board 1902 by coupling components 1916. The coupling components 1916 may electrically and mechanically couple the package-on-interposer structure 1936 to the circuit board 1902, and may include solder balls (as shown in FIG. 19), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1936 may include an integrated circuit component 1920 coupled to an interposer 1904 by coupling components 1918. The coupling components 1918 may take any suitable form for the application, such as the forms discussed above with reference to the coupling components 1916. Although a single integrated circuit component 1920 is shown in FIG. 19, multiple integrated circuit components may be coupled to the interposer 1904; indeed, additional interposers may be coupled to the interposer 1904. The interposer 1904 may provide an intervening substrate used to bridge the circuit board 1902 and the integrated circuit component 1920.

The integrated circuit component 1920 may be a packaged or unpacked integrated circuit product that includes one or more integrated circuit dies (e.g., the die 1602 of FIG. 16, the integrated circuit device 1700 of FIG. 17) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1920, a single monolithic integrated circuit die comprises solder bumps attached to contacts on the die. The solder bumps allow the die to be directly attached to the interposer 1904. The integrated circuit component 1920 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1920 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1920 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1920 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1904 may spread connections to a wider pitch or reroute a connection to a different connection. For example, the interposer 1904 may couple the integrated circuit component 1920 to a set of ball grid array (BGA) conductive contacts of the coupling components 1916 for coupling to the circuit board 1902. In the embodiment illustrated in FIG. 19, the integrated circuit component 1920 and the circuit board 1902 are attached to opposing sides of the interposer 1904; in other embodiments, the integrated circuit component 1920 and the circuit board 1902 may be attached to a same side of the interposer 1904. In some embodiments, three or more components may be interconnected by way of the interposer 1904.

In some embodiments, the interposer 1904 may be formed as a PCB, including multiple metal layers separated from one another by layers of dielectric material and interconnected by electrically conductive vias. In some embodiments, the interposer 1904 may be formed of an epoxy resin, a fiberglass-reinforced epoxy resin, an epoxy resin with inorganic fillers, a ceramic material, or a polymer material such as polyimide. In some embodiments, the interposer 1904 may be formed of alternate rigid or flexible materials that may include the same materials described above for use in a semiconductor substrate, such as silicon, germanium, and other group III-V and group IV materials. The interposer 1904 may include metal interconnects 1908 and vias 1910, including but not limited to through hole vias 1910-1 (that extend from a first face 1950 of the interposer 1904 to a second face 1954 of the interposer 1904), blind vias 1910-2 (that extend from the first or second faces 1950 or 1954 of the interposer 1904 to an internal metal layer), and buried vias 1910-3 (that connect internal metal layers).

In some embodiments, the interposer 1904 can comprise a silicon interposer. Through silicon vias (TSV) extending through the silicon interposer can connect connections on a first face of a silicon interposer to an opposing second face of the silicon interposer. In some embodiments, an interposer 1904 comprising a silicon interposer can further comprise one or more routing layers to route connections on a first face of the interposer 1904 to an opposing second face of the interposer 1904.

The interposer 1904 may further include embedded devices 1914, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1904. The package-on-interposer structure 1936 may take the form of any of the package-on-interposer structures known in the art. In embodiments where the interposer is a non-printed circuit board

The integrated circuit device assembly 1900 may include an integrated circuit component 1924 coupled to the first face 1940 of the circuit board 1902 by coupling components 1922. The coupling components 1922 may take the form of any of the embodiments discussed above with reference to the coupling components 1916, and the integrated circuit component 1924 may take the form of any of the embodiments discussed above with reference to the integrated circuit component 1920.

The integrated circuit device assembly 1900 illustrated in FIG. 19 includes a package-on-package structure 1934 coupled to the second face 1942 of the circuit board 1902 by coupling components 1928. The package-on-package structure 1934 may include an integrated circuit component 1926 and an integrated circuit component 1932 coupled together by coupling components 1930 such that the integrated circuit component 1926 is disposed between the circuit board 1902 and the integrated circuit component 1932. The coupling components 1928 and 1930 may take the form of any of the embodiments of the coupling components 1916 discussed above, and the integrated circuit components 1926 and 1932 may take the form of any of the embodiments of the integrated circuit component 1920 discussed above. The package-on-package structure 1934 may be configured in accordance with any of the package-on-package structures known in the art.

FIG. 20 is a block diagram of an example electrical device 2000 that may include one or more of the probabilistic computing devices disclosed herein. For example, any suitable ones of the components of the electrical device 2000 may include one or more of the integrated circuit device assemblies 1900, integrated circuit components 1920, integrated circuit devices 1700, or integrated circuit dies 1602 disclosed herein. A number of components are illustrated in FIG. 20 as included in the electrical device 2000, but any one or more of these components may be omitted or duplicated, as suitable for the application. In some embodiments, some or all of the components included in the electrical device 2000 may be attached to one or more motherboards mainboards, or system boards. In some embodiments, one or more of these components are fabricated onto a single system-on-a-chip (SoC) die.

Additionally, in various embodiments, the electrical device 2000 may not include one or more of the components illustrated in FIG. 20, but the electrical device 2000 may include interface circuitry for coupling to the one or more components. For example, the electrical device 2000 may not include a display device 2006, but may include display device interface circuitry (e.g., a connector and driver circuitry) to which a display device 2006 may be coupled. In another set of examples, the electrical device 2000 may not include an audio input device 2024 or an audio output device 2008, but may include audio input or output device interface circuitry (e.g., connectors and supporting circuitry) to which an audio input device 2024 or audio output device 2008 may be coupled.

The electrical device 2000 may include one or more processor units 2002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 2002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 2000 may include a memory 2004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 2004 may include memory that is located on the same integrated circuit die as the processor unit 2002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 2000 can comprise one or more processor units 2002 that are heterogeneous or asymmetric to another processor unit 2002 in the electrical device 2000. There can be a variety of differences between the processing units 2002 in a system in terms of a spectrum of metrics of merit including architectural, microarchitectural, thermal, power consumption characteristics, and the like. These differences can effectively manifest themselves as asymmetry and heterogeneity among the processor units 2002 in the electrical device 2000.

In some embodiments, the electrical device 2000 may include a communication component 2012 (e.g., one or more communication components). For example, the communication component 2012 can manage wireless communications for the transfer of data to and from the electrical device 2000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 2012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 2012 may operate in accordance with other wireless protocols in other embodiments. The electrical device 2000 may include an antenna 2022 to facilitate wireless communications and/or to receive other wireless communications (such as AM or FM radio transmissions).

In some embodiments, the communication component 2012 may manage wired communications, such as electrical, optical, or any other suitable communication protocols (e.g., IEEE 802.3 Ethernet standards). As noted above, the communication component 2012 may include multiple communication components. For instance, a first communication component 2012 may be dedicated to shorter-range wireless communications such as Wi-Fi or Bluetooth, and a second communication component 2012 may be dedicated to longer-range wireless communications such as global positioning system (GPS), EDGE, GPRS, CDMA, WiMAX, LTE, EV-DO, or others. In some embodiments, a first communication component 2012 may be dedicated to wireless communications, and a second communication component 2012 may be dedicated to wired communications.

The electrical device 2000 may include battery/power circuitry 2014. The battery/power circuitry 2014 may include one or more energy storage devices (e.g., batteries or capacitors) and/or circuitry for coupling components of the electrical device 2000 to an energy source separate from the electrical device 2000 (e.g., AC line power).

The electrical device 2000 may include a display device 2006 (or corresponding interface circuitry, as discussed above). The display device 2006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 2000 may include an audio output device 2008 (or corresponding interface circuitry, as discussed above). The audio output device 2008 may include any embedded or wired or wirelessly connected external device that generates an audible indicator, such speakers, headsets, or earbuds.

The electrical device 2000 may include an audio input device 2024 (or corresponding interface circuitry, as discussed above). The audio input device 2024 may include any embedded or wired or wirelessly connected device that generates a signal representative of a sound, such as microphones, microphone arrays, or digital instruments (e.g., instruments having a musical instrument digital interface (MIDI) output). The electrical device 2000 may include a Global Navigation Satellite System (GNSS) device 2018 (or corresponding interface circuitry, as discussed above), such as a Global Positioning System (GPS) device. The GNSS device 2018 may be in communication with a satellite-based system and may determine a geolocation of the electrical device 2000 based on information received from one or more GNSS satellites, as known in the art.

The electrical device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The electrical device 2000 may include an other input device 2020 (or corresponding interface circuitry, as discussed above). Examples of the other input device 2020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 2000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 2000 may be any other electronic device that processes data. In some embodiments, the electrical device 2000 may comprise multiple discrete physical components. Given the range of devices that the electrical device 2000 can be manifested as in various embodiments, in some embodiments, the electrical device 2000 can be referred to as a computing device or a computing system.

As used in this application and the claims, a list of items joined by the term “and/or” can mean any combination of the listed items. For example, the phrase “A, B and/or C” can mean A; B; C; A and B; A and C; B and C; or A, B and C. As used in this application and the claims, a list of items joined by the term “at least one of” can mean any combination of the listed terms. For example, the phrase “at least one of A, B or C” can mean A; B; C; A and B; A and C; B and C; or A, B, and C. Moreover, as used in this application and the claims, a list of items joined by the term “one or more of” can mean any combination of the listed terms. For example, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all of the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

The disclosed methods, apparatuses, and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

The following examples pertain to additional embodiments of technologies disclosed herein.

Example 1 is an apparatus comprising: a first electrode; a second electrode; and a magnetic tunnel junction comprising: a first synthetic antiferromagnet; a second synthetic antiferromagnet; an insulating layer positioned between the first synthetic antiferromagnet and the second synthetic antiferromagnet, the magnetic tunnel junction positioned between the first electrode and the second electrode; and an antiferromagnet positioned between the first electrode and the first synthetic antiferromagnet.

Example 2 comprises the apparatus of example 1, wherein the antiferromagnet comprises: iridium and manganese; chromium; iron and manganese; nickel and oxygen; or iron and oxygen.

Example 3 comprises the apparatus of example 1 or 2, wherein the first synthetic antiferromagnet comprises: a first ferromagnet; a second ferromagnet; and a nonmagnetic layer positioned between the first ferromagnet and the second ferromagnet.

Example 4 comprises the apparatus of example 3, wherein the first ferromagnet of the first synthetic antiferromagnet comprises: cobalt and iron; cobalt, iron, and boron; or iron and boron; and wherein the second ferromagnet of the first synthetic antiferromagnet comprises: cobalt and iron; cobalt, iron, and boron; or iron and boron.

Example 5 comprises the apparatus of example 3, wherein the nonmagnetic layer of the first synthetic antiferromagnet comprises ruthenium, copper, platinum, tungsten, iridium, chromium, or gold.

Example 6 comprises the apparatus of any one of examples 1-5, wherein the second synthetic antiferromagnet comprises: a first ferromagnet; a second ferromagnet; and a nonmagnetic layer positioned between the first ferromagnet and the second ferromagnet.

Example 7 comprises the apparatus of example 6, wherein the first ferromagnet of the second synthetic antiferromagnet comprises: cobalt; iron; cobalt and iron; cobalt, iron, and boron; iron and boron; nickel and iron; iron and platinum; cobalt and platinum; manganese and bismuth; nickel, manganese, and antimony; lanthanum, strontium, manganese, and oxygen; yttrium, iron, and oxygen; chromium and oxygen; strontium, iron, molybdenum, and oxygen; or iron and oxide; and wherein the second ferromagnet of the second synthetic antiferromagnet comprises: cobalt; iron; cobalt and iron; cobalt, iron, and boron; iron and boron; nickel and iron; iron and platinum; cobalt and platinum; manganese and bismuth; nickel, manganese, and lead; lanthanum, strontium, manganese, and oxygen; yttrium, iron, and oxygen; chromium and oxygen; strontium, iron, molybdenum, and oxygen; or iron and oxide.

Example 8 comprises the apparatus of example 6, wherein the first ferromagnet of the second synthetic antiferromagnet comprises: cobalt and iron; cobalt, iron, and boron; or iron and boron; and wherein the second ferromagnet of the second synthetic antiferromagnet comprises: cobalt and iron; cobalt, iron, and boron; or iron and boron.

Example 9 comprises the apparatus of example 6, wherein individual of the first ferromagnet of the second synthetic antiferromagnet and the second ferromagnet of the second synthetic antiferromagnet comprise: a first layer comprising cobalt; and a second layer comprising platinum or nickel.

Example 10 comprises the apparatus of example 6, wherein individual of the first ferromagnet of the second synthetic antiferromagnet and the second ferromagnet of the second synthetic antiferromagnet comprise a periodic multilayer structure comprising: a plurality of first layers comprising cobalt; and a plurality of second layers comprising platinum or nickel, wherein a period of the periodic multilayer structure comprises one of the first layers and one of the second layers, the one of the first layers positioned adjacent to the one of the second layers.

Example 11 comprises the apparatus of example 6, wherein the first ferromagnet of the second synthetic antiferromagnet and the second ferromagnet of the second synthetic antiferromagnet comprise: a first layer comprising cobalt; and a second layer positioned adjacent to the first layer comprising cobalt and platinum.

Example 12 comprises the apparatus of example 6, wherein the nonmagnetic layer of the second synthetic antiferromagnet comprises ruthenium, copper, platinum, tungsten, iridium, chromium, or gold.

Example 13 comprises the apparatus of any one of examples 1-12, wherein the insulating layer comprises magnesium and oxygen.

Example 14 comprises the apparatus of any one of examples 1-13, wherein the first electrode comprises one or more conductive layers, one of the one or more conductive layers positioned adjacent to the antiferromagnet.

Example 15 comprises the apparatus of example 14, the one or more conductive layers comprising: a first conductive layer comprising tantalum, the first conductive layer positioned adjacent to the antiferromagnet; and a second conductive layer comprising ruthenium, the second conductive layer positioned adjacent to the first conductive layer.

Example 16 comprises the apparatus of any one of examples 1-15, wherein the second electrode comprises one or more conductive layers, one of the one or more conductive layers positioned adjacent to the second synthetic antiferromagnet.

Example 17 comprises the apparatus of example 16, the second synthetic antiferromagnet comprising: a first ferromagnet positioned adjacent to the insulating layer; a second ferromagnet; and a nonmagnetic layer positioned between the first ferromagnet and the second ferromagnet; the one or more conductive layers comprising: a first conductive layer comprising tantalum, the first conductive layer positioned adjacent to the second ferromagnet of the second synthetic antiferromagnet; a second conductive layer comprising ruthenium, the second conductive layer positioned adjacent to the first conductive layer; and a third conductive layer comprising tantalum, the first conductive layer positioned adjacent to the second ferromagnet.

Example 18 comprises the apparatus of example 17, wherein the one of the one or more conductive layers of the second electrode is positioned vertically adjacent to the magnetic tunnel junction, the apparatus further comprising a conductive trace portion positioned horizontally adjacent to the one or more conductive layers of the second electrode.

Example 19 comprises the apparatus of example 18, the second synthetic antiferromagnet comprising: a first ferromagnet positioned adjacent to the insulating layer; a second ferromagnet; and a second insulating layer positioned between the first ferromagnet and the second ferromagnet; the one or more conductive layers comprising: a first conductive layer comprising tantalum, the first conductive layer positioned adjacent to the second ferromagnet; a second conductive layer comprising tantalum; and a third conductive layer comprising ruthenium, the third conductive layer positioned adjacent to the first conductive layer and the second conductive layer.

Example 20 comprises the apparatus of any one of examples 1-19, wherein the magnetic tunnel junction is a first magnetic tunnel junction, the insulating layer of the first magnetic tunnel junction is a first insulating layer, the apparatus further comprising: a third electrode; a fourth electrode; a second magnetic tunnel junction comprising: a third synthetic antiferromagnet; a fourth synthetic antiferromagnet; and a second insulating layer positioned between the third synthetic antiferromagnet and the fourth synthetic antiferromagnet; a second antiferromagnet positioned between the third electrode and the third synthetic antiferromagnet of the second magnetic tunnel junction, the second magnetic tunnel junction positioned between the third electrode and the fourth electrode; and one or more conductive traces and/or one or more vias to provide an electrically conductive path between the second electrode and the third electrode, the one or more vias comprising one or more metals.

Example 21 comprises the apparatus of example 20, the apparatus further comprising: an inverter comprising an input electrode and an output electrode; and one or more additional conductive traces and/or one or more additional vias to provide a conductive path between the third electrode and the input electrode of the inverter.

Example 22 comprises the apparatus of example 20, wherein the second antiferromagnet comprises: iridium and manganese; chromium; iron and manganese; nickel and oxygen; or iron and oxygen.

Example 23 comprises the apparatus of example 20 or 22, wherein the third synthetic antiferromagnet comprises: a first ferromagnet; a second ferromagnet; and a nonmagnetic layer positioned between the first ferromagnet and the second ferromagnet.

Example 24 comprises the apparatus of example 23, wherein the first ferromagnet of the third synthetic antiferromagnet comprises: cobalt and iron; cobalt, iron, and boron; or iron and boron; and wherein the second ferromagnet of the third synthetic antiferromagnet comprises: cobalt and iron; cobalt, iron, and boron; or iron and boron.

Example 25 comprises the apparatus of example 23, wherein the nonmagnetic layer of the third synthetic antiferromagnet comprises ruthenium, copper, platinum, tungsten, iridium, chromium, or gold.

Example 26 comprises the apparatus of any one of examples 20-25, wherein the fourth synthetic antiferromagnet comprises: a first ferromagnet; a second ferromagnet; and a nonmagnetic layer positioned between the first ferromagnet and the second ferromagnet.

Example 27 comprises the apparatus of example 26, wherein the first ferromagnet of the fourth synthetic antiferromagnet comprises: cobalt; iron; cobalt and iron; cobalt, iron, and boron; iron and boron; nickel and iron; iron and platinum; cobalt and platinum; manganese and bismuth; nickel, manganese, and antimony; lanthanum, strontium, manganese, and oxygen; yttrium, iron, and oxygen; chromium and oxygen; strontium, iron, molybdenum, and oxygen; or iron and oxide; and wherein the second ferromagnet of the fourth synthetic antiferromagnet comprises: cobalt; iron; cobalt and iron; cobalt, iron, and boron; iron and boron; nickel and iron; iron and platinum; cobalt and platinum; manganese and bismuth; nickel, manganese, and lead; lanthanum, strontium, manganese, and oxygen; yttrium, iron, and oxygen; chromium and oxygen; strontium, iron, molybdenum, and oxygen; or iron and oxide.

Example 28 comprises the apparatus of example 26, wherein the first ferromagnet of the fourth synthetic antiferromagnet comprises: cobalt and iron; cobalt, iron, and boron; or iron and boron; and wherein the second ferromagnet of the fourth synthetic antiferromagnet comprises: cobalt and iron; cobalt, iron, and boron; or iron and boron.

Example 29 comprises the apparatus of example 26, wherein individual of the first ferromagnet of the fourth synthetic antiferromagnet and the second ferromagnet of the fourth synthetic antiferromagnet comprise: a first layer comprising cobalt; and a second layer comprising platinum or nickel.

Example 30 comprises the apparatus of example 26, wherein individual of the first ferromagnet of the fourth synthetic antiferromagnet and the second ferromagnet of the fourth synthetic antiferromagnet comprise a periodic multilayer structure comprising: a plurality of first layers comprising cobalt; and a plurality of second layers comprising platinum or nickel, wherein a period of the periodic multilayer structure comprises one of the first layers and one of the second layers, the one of the first layers positioned adjacent to the one of the second layers.

Example 31 comprises the apparatus of example 26, wherein the first ferromagnet of the fourth synthetic antiferromagnet and the second ferromagnet of the fourth synthetic antiferromagnet comprise: a first layer comprising cobalt; and a second layer positioned adjacent to the first layer comprising cobalt and platinum.

Example 32 comprises the apparatus of example 26, wherein the nonmagnetic layer of the fourth synthetic antiferromagnet comprises ruthenium, copper, platinum, tungsten, iridium, chromium, or gold.

Example 33 comprises the apparatus of example 26, wherein the second insulating layer comprises magnesium and oxygen.

Example 34 comprises the apparatus of any one of examples 20-33, wherein the third electrode comprises one or more conductive layers, one of the one or more conductive layers positioned adjacent to the antiferromagnet.

Example 35 comprises the apparatus of example 34, the one or more conductive layers comprising: a first conductive layer comprising tantalum, the first conductive layer positioned adjacent to the second antiferromagnet; and a second conductive layer comprising ruthenium, the second conductive layer positioned adjacent to the first conductive layer.

Example 36 comprises the apparatus of any one of examples 20-36, wherein the fourth electrode comprises one or more conductive layers, one of the one or more conductive layers positioned adjacent to the fourth synthetic antiferromagnet.

Example 37 comprises the apparatus of example 36, the fourth synthetic antiferromagnet comprising: a first ferromagnet positioned adjacent to the second insulating layer; a second ferromagnet; and a nonmagnetic layer positioned between the first ferromagnet and the second ferromagnet; the one or more conductive layers comprising: a first conductive layer comprising tantalum, the first conductive layer positioned adjacent to the second ferromagnet of the second synthetic antiferromagnet; a second conductive layer comprising ruthenium, the second conductive layer positioned adjacent to the first conductive layer; and a third conductive layer comprising tantalum, the first conductive layer positioned adjacent to the second ferromagnet.

Example 38 comprises the apparatus of example 37, wherein the one of the one or more conductive layers of the fourth electrode is positioned vertically adjacent to the magnetic tunnel junction, the apparatus further comprising a conductive trace portion positioned horizontally adjacent to the one or more conductive layers of the fourth electrode.

Example 39 comprises the apparatus any one of examples 1-38, wherein the apparatus is located on a wafer.

Example 40 comprises the apparatus of any one of examples 1-38, wherein the apparatus is a processing unit.

Example 41 comprises the apparatus of any one of examples 1-38, wherein the apparatus is an integrated circuit component.

Example 42 comprises the apparatus of any one of examples 1-38, wherein the apparatus further comprises one or more transistors.

Example 43 comprises the apparatus of any one of examples 1-38, wherein the apparatus comprises: a printed circuit board; and a first integrated circuit component attached to the printed circuit board, the first integrated circuit component comprising the first electrode, the magnetic tunnel junction, and the second electrode.

Example 44 comprises the apparatus of example 43, wherein the apparatus further comprises one or more second integrated circuit components attached to the printed circuit board.

Example 45 comprises the apparatus of example 43, wherein the apparatus further comprises a housing enclosing the printed circuit board and the first integrated circuit component.

Example 46 is a method comprising: forming first synthetic antiferromagnet; forming an insulating layer adjacent to the first synthetic antiferromagnet; forming a second synthetic antiferromagnet adjacent to the insulating layer; and forming an antiferromagnet adjacent to the second synthetic antiferromagnet.

Example 47 comprises the method of example 46, further comprising: forming a first electrode prior to forming the first synthetic antiferromagnet, the first synthetic antiferromagnet formed adjacent to the first electrode; and forming a second electrode adjacent to the antiferromagnet.

Example 48 comprises the method of example 46 or 47, further comprising etching a hole in an interlayer dielectric prior to forming the first synthetic antiferromagnet, wherein the first synthetic antiferromagnet, the insulating layer, the second synthetic antiferromagnet, and the antiferromagnet are formed in the hole.

Example 49 comprises the method of any one of examples 46-48, wherein forming the first synthetic antiferromagnet comprises: forming a first ferromagnet; forming a first insulating layer adjacent to the first ferromagnet; and forming a second ferromagnet adjacent to the first insulating layer; and wherein forming the second synthetic antiferromagnet comprises: forming a third ferromagnet; forming a second insulating layer adjacent to the third ferromagnet; and forming a fourth ferromagnet adjacent to the second insulating layer.

Example 50 comprises the method of any one of examples 46-49, wherein the antiferromagnet comprises: iridium and manganese; chromium; iron and manganese; nickel and oxygen; or iron and oxygen.

Example 51 comprises the method of any one of examples 46-50, wherein the first synthetic antiferromagnet comprises: a first ferromagnet; a second ferromagnet; and a nonmagnetic layer positioned between the first ferromagnet and the second ferromagnet.

Example 52 comprises the method of example 51, wherein the first ferromagnet of the first synthetic antiferromagnet comprises: cobalt and iron; cobalt, iron, and boron; or iron and boron; and wherein the second ferromagnet of the first synthetic antiferromagnet comprises: cobalt and iron; cobalt, iron, and boron; or iron and boron.

Example 53 comprises the method of example 51, wherein the nonmagnetic layer of the first synthetic antiferromagnet comprises ruthenium, copper, platinum, tungsten, iridium, chromium, or gold.

Example 54 comprises the method of any one of examples 46-53, wherein the second synthetic antiferromagnet comprises: a first ferromagnet; a second ferromagnet; and a nonmagnetic layer positioned between the first ferromagnet and the second ferromagnet.

Example 55 comprises the method of example 54, wherein the first ferromagnet of the second synthetic antiferromagnet comprises: cobalt; iron; cobalt and iron; cobalt, iron, and boron; iron and boron; nickel and iron; iron and platinum; cobalt and platinum; manganese and bismuth; nickel, manganese, and antimony; lanthanum, strontium, manganese, and oxygen; yttrium, iron, and oxygen; chromium and oxygen; strontium, iron, molybdenum, and oxygen; or iron and oxide; and wherein the second ferromagnet of the second synthetic antiferromagnet comprises: cobalt; iron; cobalt and iron; cobalt, iron, and boron; iron and boron; nickel and iron; iron and platinum; cobalt and platinum; manganese and bismuth; nickel, manganese, and lead; lanthanum, strontium, manganese, and oxygen; yttrium, iron, and oxygen; chromium and oxygen; strontium, iron, molybdenum, and oxygen; or iron and oxide.

Example 56 comprises the method of example 54, wherein the first ferromagnet of the second synthetic antiferromagnet comprises: cobalt and iron; cobalt, iron, and boron; or iron and boron; and wherein the second ferromagnet of the second synthetic antiferromagnet comprises: cobalt and iron; cobalt, iron, and boron; or iron and boron.

Example 57 comprises the method of example 54, wherein individual of the first ferromagnet of the second synthetic antiferromagnet and the second ferromagnet of the second synthetic antiferromagnet comprise: a first layer comprising cobalt; and a second layer comprising platinum or nickel.

Example 58 comprises the method of example 54, wherein individual of the first ferromagnet of the second synthetic antiferromagnet and the second ferromagnet of the second synthetic antiferromagnet comprise a periodic multilayer structure comprising: a plurality of first layers comprising cobalt; and a plurality of second layers comprising platinum or nickel, wherein a period of the periodic multilayer structure comprises one of the first layers and one of the second layers, the one of the first layers positioned adjacent to the one of the second layers.

Example 59 comprises the method of example 54, wherein the first ferromagnet of the second synthetic antiferromagnet and the second ferromagnet of the second synthetic antiferromagnet comprise: a first layer comprising cobalt; and a second layer positioned adjacent to the first layer comprising cobalt and platinum.

Example 60 comprises the method of example 54, wherein the nonmagnetic layer of the second synthetic antiferromagnet comprises ruthenium, copper, platinum, tungsten, iridium, chromium, or gold.

Example 61 comprises the method of any one of examples 46-60, wherein the insulating layer comprises magnesium and oxygen.

Example 62 comprises the method of any one of examples 46-61, wherein the first electrode comprises one or more conductive layers, one of the one or more conductive layers positioned adjacent to the antiferromagnet.

Example 63 comprises the method of example 62, the one or more conductive layers comprising: a first conductive layer comprising tantalum, the first conductive layer positioned adjacent to the antiferromagnet; and a second conductive layer comprising ruthenium, the second conductive layer positioned adjacent to the first conductive layer.

Example 64 comprises the method of example 62, wherein the second electrode comprises one or more conductive layers, one of the one or more conductive layers positioned adjacent to the second synthetic antiferromagnet.

Example 65 comprises the method of example 64, the second synthetic antiferromagnet comprising: a first ferromagnet positioned adjacent to the insulating layer; a second ferromagnet; and a nonmagnetic layer positioned between the first ferromagnet and the second ferromagnet; the one or more conductive layers comprising: a first conductive layer comprising tantalum, the first conductive layer positioned adjacent to the second ferromagnet of the second synthetic antiferromagnet; a second conductive layer comprising ruthenium, the second conductive layer positioned adjacent to the first conductive layer; and a third conductive layer comprising tantalum, the first conductive layer positioned adjacent to the second ferromagnet.

Example 66 comprises the method of example 65, the second synthetic antiferromagnet comprising: a first ferromagnet positioned adjacent to the insulating layer; a second ferromagnet; and a second insulating layer positioned between the first ferromagnet and the second ferromagnet; the one or more conductive layers comprising: a first conductive layer comprising tantalum, the first conductive layer positioned adjacent to the second ferromagnet; a second conductive layer comprising tantalum; and a third conductive layer comprising ruthenium, the third conductive layer positioned adjacent to the first conductive layer and the second conductive layer.

1. An apparatus comprising:
a first electrode;
a second electrode; and
a magnetic tunnel junction comprising:
a first synthetic antiferromagnet;
a second synthetic antiferromagnet;
an insulating layer positioned between the first synthetic antiferromagnet and the second synthetic antiferromagnet, the magnetic tunnel junction positioned between the first electrode and the second electrode; and
an antiferromagnet positioned between the first electrode and the first synthetic antiferromagnet.

2. The apparatus of claim 1, wherein the antiferromagnet comprises:
iridium and manganese;
chromium;
iron and manganese;
nickel and oxygen; or
iron and oxygen.

3. The apparatus of claim 1, wherein the first synthetic antiferromagnet comprises:
a first ferromagnet;
a second ferromagnet; and
a nonmagnetic layer positioned between the first ferromagnet and the second ferromagnet.

4. The apparatus of claim 3,
wherein the first ferromagnet of the first synthetic antiferromagnet comprises:
cobalt and iron;
cobalt, iron, and boron; or
iron and boron; and
wherein the second ferromagnet of the first synthetic antiferromagnet comprises:
cobalt and iron;
cobalt, iron, and boron; or
iron and boron.

5. The apparatus of claim 3, wherein the nonmagnetic layer of the first synthetic antiferromagnet comprises ruthenium, copper, platinum, tungsten, iridium, chromium, or gold.

6. The apparatus of claim 1, wherein the second synthetic antiferromagnet comprises:
a first ferromagnet;
a second ferromagnet; and
a nonmagnetic layer positioned between the first ferromagnet and the second ferromagnet.

7. The apparatus of claim 6,
wherein the first ferromagnet of the second synthetic antiferromagnet comprises:
cobalt;
iron;
cobalt and iron;
cobalt, iron, and boron;
iron and boron;
nickel and iron;
iron and platinum;
cobalt and platinum;
manganese and bismuth;
nickel, manganese, and antimony;
lanthanum, strontium, manganese, and oxygen;
yttrium, iron, and oxygen;
chromium and oxygen;
strontium, iron, molybdenum, and oxygen; or
iron and oxide; and
wherein the second ferromagnet of the second synthetic antiferromagnet comprises:
cobalt;
iron;
cobalt and iron;
cobalt, iron, and boron;
iron and boron;
nickel and iron;
iron and platinum;
cobalt and platinum;
manganese and bismuth;
nickel, manganese, and lead;
lanthanum, strontium, manganese, and oxygen;
yttrium, iron, and oxygen;
chromium and oxygen;
strontium, iron, molybdenum, and oxygen; or
iron and oxide.

8. The apparatus of claim 6,
wherein the first ferromagnet of the second synthetic antiferromagnet comprises:
cobalt and iron;
cobalt, iron, and boron; or
iron and boron; and
wherein the second ferromagnet of the second synthetic antiferromagnet comprises:
cobalt and iron;
cobalt, iron, and boron; or
iron and boron.

9. The apparatus of claim 6, wherein individual of the first ferromagnet of the second synthetic antiferromagnet and the second ferromagnet of the second synthetic antiferromagnet comprise:
a first layer comprising cobalt; and
a second layer comprising platinum or nickel.

10. The apparatus of claim 6, wherein individual of the first ferromagnet of the second synthetic antiferromagnet and the second ferromagnet of the second synthetic antiferromagnet comprise a periodic multilayer structure comprising:
a plurality of first layers comprising cobalt; and
a plurality of second layers comprising platinum or nickel, wherein a period of the periodic multilayer structure comprises one of the first layers and one of the second layers, the one of the first layers positioned adjacent to the one of the second layers.

11. The apparatus of claim 6, wherein the first ferromagnet of the second synthetic antiferromagnet and the second ferromagnet of the second synthetic antiferromagnet comprise:
a first layer comprising cobalt; and
a second layer positioned adjacent to the first layer comprising cobalt and platinum.

12. The apparatus of claim 6, wherein the nonmagnetic layer of the second synthetic antiferromagnet comprises ruthenium, copper, platinum, tungsten, iridium, chromium, or gold.

13. The apparatus of claim 1, wherein the insulating layer comprises magnesium and oxygen.

14. The apparatus of claim 1, wherein the first electrode comprises one or more conductive layers, one of the one or more conductive layers positioned adjacent to the antiferromagnet.

15. The apparatus of claim 14, the one or more conductive layers comprising:
a first conductive layer comprising tantalum, the first conductive layer positioned adjacent to the antiferromagnet; and
a second conductive layer comprising ruthenium, the second conductive layer positioned adjacent to the first conductive layer.

16. The apparatus of claim 1, wherein the second electrode comprises one or more conductive layers, one of the one or more conductive layers positioned adjacent to the second synthetic antiferromagnet.

17. The apparatus of claim 16, the second synthetic antiferromagnet comprising:
a first ferromagnet positioned adjacent to the insulating layer;
a second ferromagnet; and
a nonmagnetic layer positioned between the first ferromagnet and the second ferromagnet;
the one or more conductive layers comprising:
a first conductive layer comprising tantalum, the first conductive layer positioned adjacent to the second ferromagnet of the second synthetic antiferromagnet;
a second conductive layer comprising ruthenium, the second conductive layer positioned adjacent to the first conductive layer; and
a third conductive layer comprising tantalum, the first conductive layer positioned adjacent to the second ferromagnet.

18. The apparatus of claim 17, wherein the one of the one or more conductive layers of the second electrode is positioned vertically adjacent to the magnetic tunnel junction, the apparatus further comprising a conductive trace portion positioned horizontally adjacent to the one or more conductive layers of the second electrode.

19. The apparatus of claim 18, the second synthetic antiferromagnet comprising:
a first ferromagnet positioned adjacent to the insulating layer;
a second ferromagnet; and
a second insulating layer positioned between the first ferromagnet and the second ferromagnet;
the one or more conductive layers comprising:
a first conductive layer comprising tantalum, the first conductive layer positioned adjacent to the second ferromagnet;
a second conductive layer comprising tantalum; and
a third conductive layer comprising ruthenium, the third conductive layer positioned adjacent to the first conductive layer and the second conductive layer.

20. The apparatus of claim 1, wherein the magnetic tunnel junction is a first magnetic tunnel junction, the insulating layer of the first magnetic tunnel junction is a first insulating layer, the apparatus further comprising:
a third electrode;
a fourth electrode;
a second magnetic tunnel junction comprising:
a third synthetic antiferromagnet;
a fourth synthetic antiferromagnet; and
a second insulating layer positioned between the third synthetic antiferromagnet and the fourth synthetic antiferromagnet;
a second antiferromagnet positioned between the third electrode and the third synthetic antiferromagnet of the second magnetic tunnel junction, the second magnetic tunnel junction positioned between the third electrode and the fourth electrode; and
one or more conductive traces and/or one or more vias to provide an electrically conductive path between the second electrode and the third electrode, the one or more vias comprising one or more metals.

21. The apparatus of claim 1, wherein the apparatus is located on a wafer.

22. The apparatus of claim 1, wherein the apparatus is an integrated circuit component.

23. The apparatus of claim 1, wherein the apparatus comprises:
a printed circuit board; and
a first integrated circuit component attached to the printed circuit board, the first integrated circuit component comprising the first electrode, the magnetic tunnel junction, and the second electrode.

24. The apparatus of claim 23, wherein the apparatus further comprises one or more second integrated circuit components attached to the printed circuit board.

25. The apparatus of claim 23, wherein the apparatus further comprises a housing enclosing the printed circuit board and the first integrated circuit component.
